(19) United States
(12) Patent Application Publication
(10) Pub. No.: US 2026/0005187 A1
(43) Pub. Date: Jan. 1, 2026

(54) METHOD INCLUDING BONDING A DIE TO A BONDING SITE AND A BONDING APPARATUS FOR CARRYING OUT THE METHOD

(71) Applicant: CANON KABUSHIKI KAISHA, Tokyo (JP)

(72) Inventors: Mario Johannes MEISSL, Austin, TX (US); Nilabh K. ROY, Cedar Park, TX (US); Byung-Jin CHOI, Austin, TX (US)

(21) Appl. No.: 18/757,263

(22) Filed: Jun. 27, 2024

(51) Int. Cl. H01L 23/00; H01L 21/304; H01L 21/78

(52) U.S. Cl. CPC H01L 24/80; H01L 21/304; H01L 21/78; H01L 24/74; H01L 2224/74; H01L 2224/80895; H01L 2224/80896; H01L 2924/40

(57) ABSTRACT

In an implementation, a method can include creating a first edge in a workpiece that includes a die and a dicing lane adjacent to the die, wherein the first edge extends to at least the dicing lane. The method can further include dicing the workpiece to separate the die from a remainder of the workpiece, wherein dicing forms an outer peripheral edge and is performed after creating the first edge, and bonding the die to a bonding site, wherein, during bonding, the outer peripheral edge does not contact an object. In another implementation, the bonding substrate can comprise a trench, and the die may or may not have an edge. In both methods, outer peripheral edges of the die may not contact any object during a bonding transfer cycle. A bonding apparatus can be adapted to carry out the method.

### FIELD OF THE DISCLOSURE

The present disclosure relates to a method including bonding a die to a bonding site and a bonding apparatus for carrying out the method.

### RELATED ART

Electronic devices can be fabricated within a semiconductor wafer. After fabrication is completed, the semiconductor wafer is diced into dies. Corners and edges of the die have rough surfaces from the dicing process and are prone to chipping and cracking. Furthermore, the corners and edges are difficult to clean. Particles generated from the dicing process can adhere to the corners and edge. Other particles can be generated during handling the dies prior to bonding and during bonding.

Some bonding processes have bonding heads with chucking surfaces that are relatively flexible and have a smaller area as compared to the areas of the dies that they are designed to hold. Other bonding heads have chucking surfaces that can be relatively rigid and have a larger area as compared to the areas of the dies that they are designed to hold. This latter set of bonding heads may further cause more particle generation when the dies contact the bonding heads during the bonding process.

A need exists to reduce the likelihood that particles will be trapped between a die and its corresponding bonding site during a bonding process.

### SUMMARY

In an aspect, a method can include creating a first edge in a workpiece that includes a die and a dicing lane adjacent to the die, wherein the first edge extends from a first major surface of the die to at least the dicing lane. The method can include dicing the workpiece to separate the die from a remainder of the workpiece, wherein dicing forms an outer peripheral edge of the die and is performed after creating the first edge. The method can further include bonding the die to a bonding site, wherein, during bonding, the outer peripheral edge does not contact the bonding site or does not contact a chucking surface of a bonding head chuck.

In an implementation, the method further includes bowing the die away from the chucking surface before bonding the die to the bonding site.

In another implementation, creating the first edge comprises etching the workpiece.

In a further implementation, creating a second edge in the workpiece, wherein the second edge extends from a second major surface of the die at least to the dicing lane, and the second major surface is opposite the first major surface.

In a more particular implementation, the method further includes backgrinding or lapping the workpiece, wherein backgrinding is performed after creating the first edge and before creating the second edge.

In a still more particular implementation, backgrinding or lapping the workpiece is performed such that a feature is exposed along a background surface.

In another still more particular implementation, backgrinding or lapping the workpiece is performed such that the feature includes a through-substrate via.

In a further still more particular implementation, backgrinding or lapping the workpiece is performed such that the feature is an alignment feature.

In another more particular implementation, the die has a die area corresponding to the outer peripheral edge, and the chucking surface has a chucking area that is larger than the die area.

In still a more particular implementation, bonding the die to the bonding site is performed such that, wherein, during bonding, the outer peripheral edge does not contact the chucking surface of the bonding head chuck.

In another particular implementation, during transferring the die, the first edge has a first sidewall, a second sidewall, and a rounded corner between the first sidewall and the second sidewall.

In another implementation, creating the first edge is performed such that a transition from the first major surface to a bottom surface of the first edge is characterized by a step.

In yet another more particular implementation, creating the first edge is performed such that the first edge has an arc shape or a chamfered shape, wherein the arc shape or the chamfered shape extends laterally in a range from 2% to 100% of a distance from the first major surface to the dicing lane.

In another implementation, bonding the die to the bonding site is performed such that the bonding site is part of a bonding substrate that defines a trench, and, after bonding the die to the bonding site, the outer peripheral edge overlaps the trench.

In a further implementation, the method further includes performing a check to ensure the first edge is on the die before bonding the die to the bonding site.

In another implementation, a method of manufacturing a device can include creating a first edge in a workpiece that includes a die and a dicing lane adjacent to the die, wherein the first edge extends from a first major surface of the die at least to the dicing lane; dicing the workpiece to separate the die from a remainder of the workpiece, wherein dicing forms an outer peripheral edge of the die and is performed after creating the first edge; and bonding the die to a bonding site, wherein, during bonding, the outer peripheral edge does not contact the bonding site or does not contact a chucking surface of a bonding head chuck.

In another aspect, a method of manufacturing a device can include creating a first edge in a workpiece that includes a die and a dicing lane adjacent to the die, wherein the first edge extends from a first major surface of the die at least to the dicing lane The method can further include creating a second edge in the workpiece define a second recession within a second buffer region of the die, wherein the second edge extends from a second major surface that is opposite the first major surface, and the second edge overlaps or underlaps at least a portion of the first edge and extends laterally at least to the dicing lane; dicing the workpiece along the dicing lane to separate the die from a remainder of the workpiece, wherein, after dicing, the die has an outer peripheral edge between the first major surface and the second major surface; transferring the die to a bonding head having a bonding head chuck having a chucking surface; and bonding the die to a bonding site.

In an implementation, the method further includes bowing the die away from the chucking surface before bonding the die, wherein, during bonding, the outer peripheral edge does not contact each of the chucking surface and the bonding site.

In another implementation, the method further includes backgrinding or lapping the workpiece, wherein backgrinding is performed after creating the first edge and before creating the second edge.

In a further aspect, a bonding apparatus can include a bonding head including a bonding head chuck, wherein the bonding head chuck has a chucking surface that has a chucking area, a first land extending to the chucking surface, and a second land extending to the chucking surface, the second land is spaced apart from and laterally surrounded by the first land, a first zone is disposed between the first land and the second land, and a second zone is laterally surrounded by the second land. The bonding apparatus can further include a first pressure actuator adapted to provide a first vacuum within the first zone, wherein the first vacuum is sufficient to a hold a die that has a first major surface and a second major surface opposite the first major surface, an outer peripheral edge between the first major surface and the second major surface, and a die area corresponding to the outer peripheral edge, wherein the die area is less than the chucking area; and a second pressure actuator and adapted to provide a pressure to the second zone, wherein the pressure is sufficient to bow the die while the die is being held by the first vacuum within the first zone. The bonding apparatus can still further include a controller adapted to provide instructions including activating the first pressure actuator to hold the die; activating the second pressure actuator to bow the die; and bonding the die to a bonding site after activating the second pressure actuator, wherein, during each of activating the second pressure actuator and bonding, the outer peripheral edge does not contact each of the chucking surface and the bonding site.

In an implementation, the bonding head further includes a bonding head body coupled to the bonding head chuck.

In another implementation, the controller is adapted to provide a further instruction including deactivating the second pressure actuator after the die contacts the bonding site and before completion of bonding the die.

### BRIEF DESCRIPTION OF THE DRAWINGS

Implementations are illustrated by way of example and are not limited in the accompanying figures.

FIG. 1 includes a conceptual view of an apparatus that can be used in transferring dies from a source substrate to a bonding substrate.

FIG. 2 includes an illustration of an exploded, cross-sectional view of a portion of a bonding head in accordance with an implementation.

FIG. 3 includes an illustration of a cross-sectional view of the bonding head of FIG. 2 after the bonding head is assembled.

FIG. 4 includes an illustration of a bottom view of a portion of a die chuck that includes a mesa, lands, zones, and flow channels.

FIG. 5 includes an illustration of a cross-sectional view of a bonding head in accordance with another implementation.

FIG. 6 includes an illustration of a bottom view of a portion of a die chuck that includes a mesa, lands, zones, pins, and flow channels in accordance with a further implementation.

FIG. 7 includes a top view of a portion of a workpiece that includes electronic component regions and buffer regions that include dicing lanes.

FIGS. 8 to 10 include a process flow diagram for a method of transferring dies from a source substrate to bonding sites of a bonding substrate.

FIG. 11 includes an illustration of a top view of the workpiece of FIG. 7 after forming mask members over electronic component regions and parts of buffer regions.

FIG. 12 includes an illustration of a cross-sectional view of the workpiece of FIG. 11 along the sectioning line 12-12 in FIG. 11.

FIG. 13 includes an illustration of a cross-sectional view of the workpiece of FIG. 12 after defining first edges extending from a major surface into the workpiece.

FIG. 14 includes an illustration of a cross-sectional view of a portion of the workpiece of FIG. 13 after removing the mask member.

FIG. 15 includes an illustration of a cross-sectional view of the workpiece of FIG. 12 after defining a first edge having a chamfered sidewall.

FIG. 16 includes an illustration of a cross-sectional view of the workpiece of FIG. 12 after defining a first edge having an arc-shaped sidewall.

FIG. 17 includes an illustration of a cross-sectional view of the workpiece of FIG. 12 after defining a first edge in accordance with a further implementation.

FIG. 18 includes an illustration of a cross-sectional view of the workpiece of FIG. 14 after turning the workpiece over and thinning the workpiece using a backgrind or lapping technique.

FIG. 19 includes an illustration of a top view of the workpiece of FIG. 18 that includes through-substrate vias and an alignment feature in accordance with an implementation;

FIG. 20 includes an illustration of a cross-sectional view of the workpiece of FIG. 18 after forming mask members over electronic component regions and parts of buffer regions.

FIG. 21 includes an illustration of a cross-sectional view of the workpiece of FIG. 20 after defining second edges extending from an opposite major surface into the workpiece.

FIG. 22 includes an illustration of a cross-sectional view of the workpiece of FIG. 21 after removing the mask member, turning the workpiece over, and coupling the workpiece to a source substrate.

FIGS. 23 and 24 include illustrations of a cross-sectional view and a top view, respectively, of the workpiece of FIG. 22 after dicing the workpiece into dies.

FIG. 25 includes an illustration of a side view of the bonding apparatus of FIG. 1 after mounting the source substrate to a source chuck and mounting a bonding substrate to a bonding chuck.

FIG. 26 includes an illustration of a side view of the bonding apparatus of FIG. 25 after transferring a set of dies to die transfer heads.

FIG. 27 includes an illustration of a side view of the bonding apparatus of FIG. 26 after positioning the set of dies for transfer to bonding heads.

FIG. 28 including an illustration of a side view of the bonding apparatus of FIG. 27 after transferring the set of dies to the bonding heads and during registration and metrology operations with respect to the set of dies and the bonding heads.

FIG. 29 includes an illustration of a cross-sectional view of the portion of a die chuck and a particular die when the particular die is being held by the die chuck.

FIG. 30 includes an illustration of a cross-sectional view of the portion of the die chuck and the particular die of FIG. 29 when the particular die is bowed.

FIG. 31 includes an illustration of a cross-sectional view of an enlarged portion of the particular die and die chuck at the location seen in FIG. 30.

FIG. 32 includes an illustration of a cross-sectional view of the portion of the die chuck, a portion of the bonding substrate, and the particular die of FIG. 30 during initial contact between the particular die and a bonding site of the bonding substrate.

FIG. 33 includes an illustration of a cross-sectional view of the portion of the die chuck, the portion of the bonding substrate, and the particular die of FIG. 32 during bonding the particular die to the bonding site of the bonding substrate.

FIG. 34 includes an illustration of a cross-sectional view of an enlarged portion of the particular die and die chuck at the location seen in FIG. 33.

FIG. 35 includes an illustration of a cross-sectional view of the bonding apparatus after bonding the set of dies to the bonding sites of the bonding substrate.

FIG. 36 includes an illustration of a cross-sectional view of a portion of a bonding substrate and a plurality of bonded dies.

FIG. 37 includes an illustration of a cross-sectional view of an enlarged portion of the portion of the bonding substrate and the plurality of bonded dies at the location seen in FIG. 36.

FIG. 38 includes an illustration of a portion of a bonding substrate and a die bonded to the bonding substrate where the bonding substrate has a trench adjacent to outer peripheral edges of the bonded die.

Skilled artisans appreciate that elements in the figures are illustrated for simplicity and clarity and have not necessarily been drawn to scale. For example, the dimensions of some of the elements in the figures can be exaggerated relative to other elements to help improve understanding of implementations of the inventive concepts.

### DETAILED DESCRIPTION

The following description in combination with the figures is provided to assist in understanding the teachings disclosed herein. The following discussion will focus on specific implementations and implementations of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and can be found in textbooks and other sources within the arts.

A die can have a first edge, a second edge, or the first and second edges extending to an outer peripheral edge of the die. The first edge, the second edge, or the first and second edges can lie at a sidewall of a mesa. The first edge, the second edge, or the first and second edges can help reduce particle issues due to particles becoming dislodged or generated along the outer peripheral edge of the die. The first edge, the second edge, or the first and second edges can reduce the likelihood that the relatively rougher and more fragile outer peripheral edge contacts a bonding site of a bonding substrate. Alternatively, or in conjunction with the first edge, the second edge, or the first and second edges, the bonding substrate may or may not have a trench that reduces the likelihood that the outer peripheral edge of the die contacts the bonding substrate. The method and bonding apparatus are well suited to, but not limited to, a hybrid bonding process.

The bonding apparatus and method are understood better after reading this specification in conjunction with the figures. Implementations described below are exemplary and do not limit the scope of the inventive concepts. While some die chucks will be described mostly with respect to an array of bonding heads, and other die chucks will be described mostly with respect to an array of die transfer seats, the die chucks for the array of bonding heads may be used for the array of die transfer seats, and the die chucks for the array of die transfer seats may be used for the array of bonding heads.

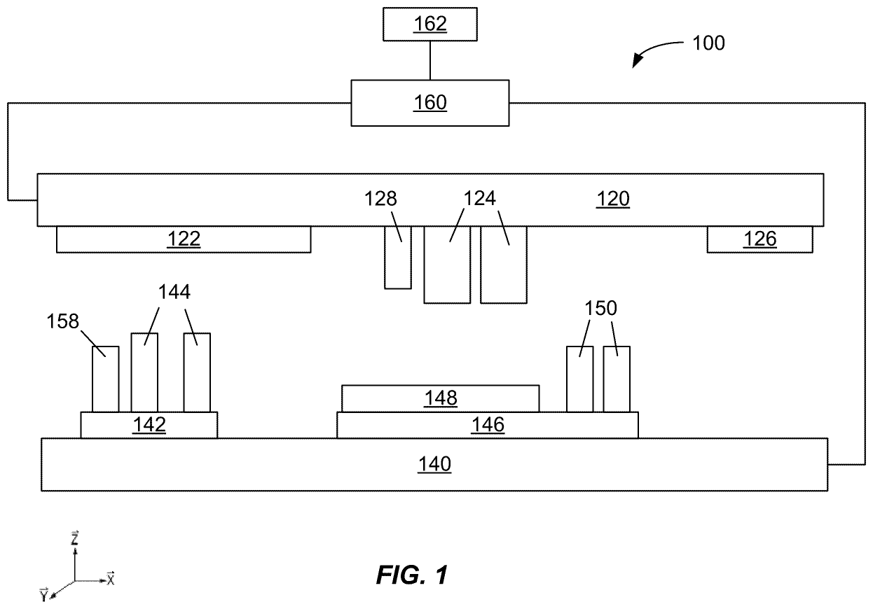

FIG. 1 includes a conceptual diagram of a bonding apparatus 100 that can be used to transfer dies coupled to a source chuck 122 to bonding sites of a bonding substrate coupled to a bonding chuck 148. The bonding apparatus 100 can be a single apparatus or more than one apparatus. In an implementation, the bonding apparatus 100 may include another apparatus or equipment not illustrated in FIG. 1.

FIG. 1 includes an equipment configuration of the bonding apparatus 100 and does not include the dies and the bonding substrate. The bonding apparatus 100 includes a bridge 120, a base 140, and a controller 160 that is coupled to the bridge 120, the base 140, or to one or more components coupled to the bridge 120 or the base 140. The bridge 120 can be coupled to a source chuck 122, an array of bonding heads 124, a reference 126 having one or more alignment marks, and registration hardware 128. The base 140 can be coupled to a die transfer carriage 142 and a bonding carriage 146.

In FIG. 1 and other figures, the bridge 120, the base 140, and components physically between the bridge 120 or the base 140 can be organized along an X-direction, a Y-direction, a Z-direction, or a combination thereof. With respect to cross-sectional or side views, the X-direction is between the left-hand and right-hand sides of the drawings, the Z-direction is between the top and bottom of the drawings, and the Y-direction is into and out of the drawing sheet. Unless explicitly stated to the contrary, rotation occurs along an X-Y plane defined by the X-direction and Y-direction.

Components within the bonding apparatus 100 will be generally described in the order in which a set of dies will be transferred from a source substrate coupled to the source chuck 122 to a bonding substrate coupled to the bonding chuck 148. Due to similarities in operation, the die transfer carriage 142 and the bonding carriage 146 are described in the same passage later in this specification.

The terms “transfer operation” and “transfer cycle” are addressed to aid in understanding implementations as described herein. A transfer operation starts no later than transferring a set of dies to a array of die transfer seats, where the set of dies will be the first set of dies transferred to the bonding substrate and ends when the last set of dies is transferred to the bonding substrate. A transfer cycle starts no later than transferring a set of dies to a array of die transfer seats until that same particular set of dies is transferred to the bonding substrate. A transfer operation can include one or more transfer cycles.

The source chuck 122 can be a vacuum chuck, a pin-type chuck, a groove-type chuck, an electrostatic chuck, an electromagnetic chuck, or the like. The source chuck 122 can be coupled to the bridge 120 by being attached to the bridge directly or can be coupled to the bridge via a carriage (not illustrated). When present, the carriage may be able to provide translating motion as described in more detail below with respect to the die transfer carriage 142 and the bonding carriage 146. The source chuck 122 has a source holding surface that faces the base 140 or a component coupled to the base 140.

The die transfer carriage 142 and the bonding carriage 146 are coupled to the base 140 and can provide translating motion along the base 140 in an X-direction, a Y-direction, or a Z-direction or rotational motion about one or more of axes, such as rotation about the Z-axis and along a plane lying along the X-direction and Y-direction. The die transfer carriage 142 and the bonding carriage 146 can be moved together or independently relative to each other. The die transfer carriage 142 and the bonding carriage 146 can be the same type or different types of carriages.

An array of die transfer seats 144 are coupled to the die transfer carriage 142 and have pick-up surfaces that face the bridge 120 or a component coupled to the bridge 120. In an implementation, the array of die transfer seats 144 can be an array of pick-up heads. In another implementation, a placement tool or an operator can place dies onto die transfer seats within the array of die transfer seats 144, and thus, the array of die transfer seats 144 do not need to pick up dies from a source substrate. The source chuck 122 may or may not be present in the bonding apparatus 100. When dies are attached to a source substrate coupled to the source chuck, a transfer operation or a transfer cycle may start when a set of dies are picked up from the source substrate by the array of die transfer seats 144.

The array of die transfer seats 144 can be arranged as a vector (a row or a column of die transfer seats) or as a matrix (at least two rows and at least two columns of die transfer seats). Regarding the matrix, the number of die transfer seats within the array of die transfer seats 144 may be different between rows, between columns, or between rows and columns. Some array configurations can include 3×1, 6×1, 2×2, 2×3, 2×4, 4×2, 10×10, or another rectangular shape, where the first number corresponds to the number of die transfer seats along a row or column, and the second number corresponds to the number of die transfer seats along the other of the row or column. In theory, dies from an entire source wafer may be transferred all at once. For such a configuration, from a top view, the array of die transfer seats 144 may have fewer die transfer seats along rows closer to the top and bottom of the array as compared to the row or the pair of rows closest to the center of the array, and the array of die transfer seats 144 may have fewer die transfer seats along columns closer to the left-hand side and right-hand side of the array as compared to the column or the pair of columns closest to the center of the array. After reading this specification, skilled artisans will be able to determine an array configuration for the array of die transfer seats 144 that meets the needs or desires for a particular application.

A hybrid bonding technique can be used to bond dies to bonding sites of the bonding substrate. The bonding apparatus can be adapted such that the array of die transfer seats 144, the array of bonding heads 124, or both arrays do not contact either or both major surfaces of a set of dies being transferred. For example, a die may have an activated surface to assist in hybrid bonding. A die can be held along sides between major surfaces of the die. If the die is too thin, a backing plate can be attached to the die. In an alternative implementation, a Bernoulli chuck may be used. In a further implementation, a die transfer seat or a bonding head can include a chuck that is a vacuum chuck, a pin-type chuck, a groove-type chuck, an electrostatic chuck, or an electromagnetic chuck.

The array of die transfer seats 144 can be adapted to have an adjustable pitch that can be reversibly changed between a source-matching pitch and a bonding head-matching pitch. The array of die transfer seats 144 or the die transfer carriage 142 can include motors, electrical components, or the like that can be activated to move die transfer seats to achieve a desired pitch. The bonding apparatus 100 can be adapted to allow at least one pitch change per transfer cycle. On average, the pitch for the array of die transfer seats 144 can be changed twice during a transfer cycle. As used herein, a pitch is the sum of a width or a length of a feature and the space between the feature and the immediately adjacent feature. The features can be dies at a source substrate, die transfer seats within the array of die transfer seats 144, bonding heads within the array of bonding heads 124, or bonding sites of the bonding substrate. The pitch along the X-direction may be the same or different from the pitch in the Y-direction.

In an implementation, the array of die transfer seats 144 can be at the source-matching pitch when picking up a set of dies coupled to the source chuck 122 and at the bonding head-matching pitch when transferring the dies to the array of bonding heads 124. The source-matching pitch for the array of die transfer seats 144 should be the same as the source pitch of dies to be picked up from a source substrate that is coupled to the source chuck 122, and the bonding head-matching pitch for the array of die transfer seats 144 should be the same as a bonding head pitch for bonding heads within the array of bonding heads 124. In practice, the source-matching pitch is usually slightly different from the source pitch, and the bonding head-matching pitch is usually slightly different from the bonding head pitch. A successful die transfer can occur when the difference between the source-matching pitch and the source pitch, the difference between the bonding head-matching pitch and the bonding head pitch, or both differences are within acceptable tolerances to allow for the proper picking up and transferring of the dies.

After the dies are transferred to the array of bonding heads 124, the pitch for the array of die transfer seats 144 can be changed from the bonding head-matching pitch to the source-matching pitch before picking up the next set of dies for the next transfer cycle. The changing of the pitch can be performed with or without human intervention. In an implementation, a signal from the bridge 120, the base 140, or any one or more components coupled to the bridge 120 or the base 140 can be transmitted to the controller 160 or a local controller that an action has been completed, and such controller can transmit a signal to change the pitch for the array of die transfer seats 144. For example, after the array of die transfer seats 144 have picked up a set of dies from the source substrate, a signal can be transmitted to the controller 160 or a local controller that picking up the set of dies has been completed. In response to the signal, the controller 160 or a local controller can transmit a signal for changing the pitch for the array of die transfer seats 144 from the source-matching pitch to the bonding head-matching pitch. After the array of die transfer seats 144 have transferred the set of dies to the array of bonding heads 124, a signal can be transmitted to the controller 160 or a local controller that the transfer from the array of die transfer seats 144 to the array of bonding heads 124 has been completed. In response to the signal, the controller 160 or a local controller can transmit a signal for changing the pitch for the array of die transfer seats 144 from the bonding head-matching pitch to the source-matching pitch.

Similar to the array of die transfer seats 144, the array of bonding heads 124 can be arranged as a vector (a row or a column of bonding heads) or as a matrix (at least two rows and at least two columns of bonding heads). Regarding the matrix, the number of bonding heads within the array of bonding heads 124 may be different between rows, between columns, or between rows and columns. Some array configurations can include 3×1, 6×1, 2×2, 2×3, 2×4, 4×2 10×10, or another rectangular shape, where the first number corresponds to the number of bonding heads along a row or column, and the second number corresponds to the number of bonding heads along the other of the row or column. In theory, dies from an entire wafer may be transferred all at once. For such a configuration, from a bottom view, the array of bonding heads 124 may have fewer bonding heads along rows closer to the top and bottom of the array as compared to the row or the pair of rows closest to the center of the array, and the array of bonding heads 124 may have fewer bonding heads along columns closer to the left-hand side and right-hand side of the array as compared to the column or the pair of columns closest to the center of the array. After reading this specification, skilled artisans will be able to determine an arrangement for the array of bonding heads 124 that meets the needs or desires for a particular application.

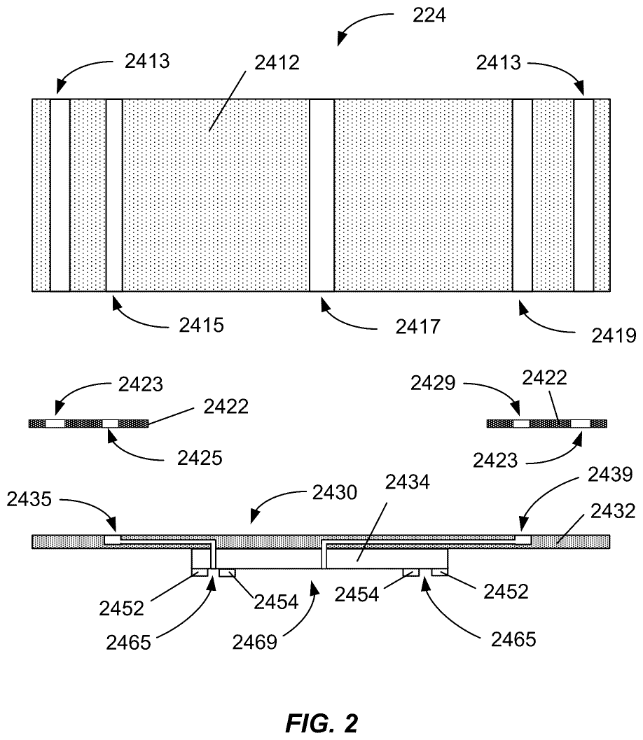

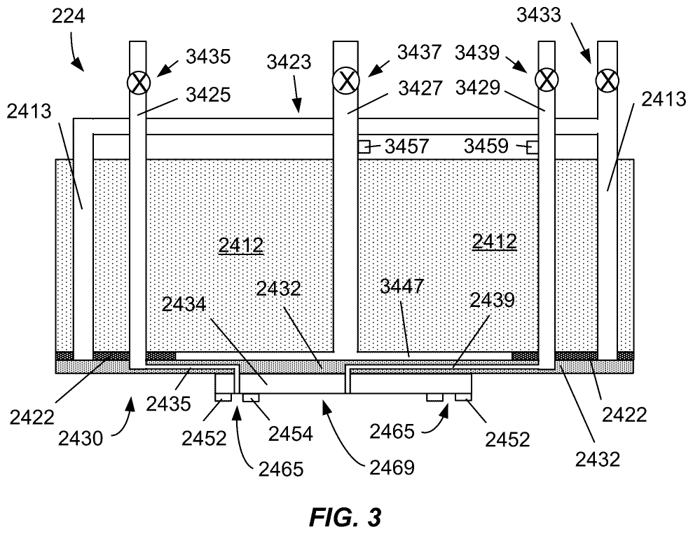

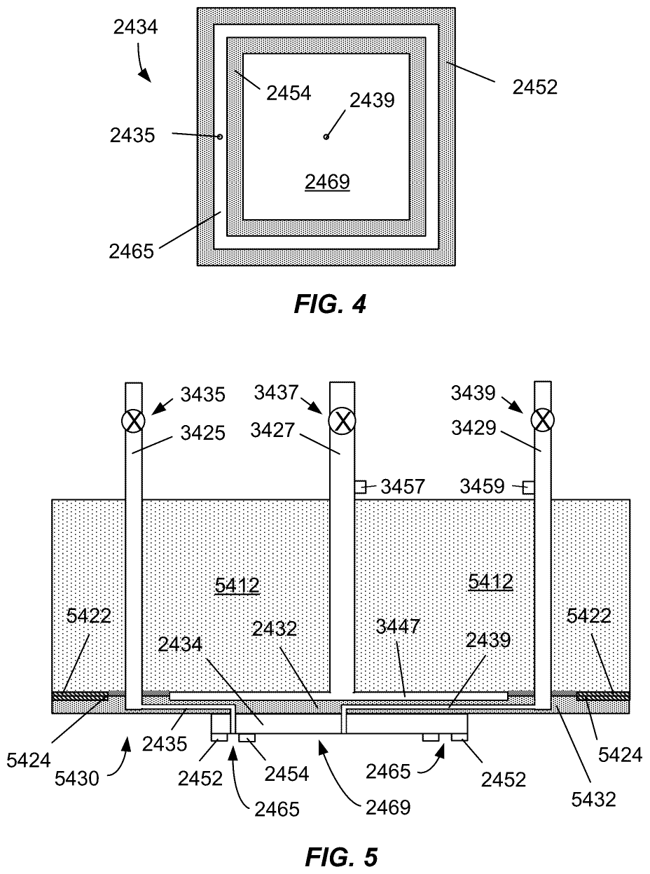

The array of bonding heads 124 are coupled to the bridge 120. Referring to FIGS. 2 to 4, a bonding head 224 can be used for any or all of the bonding heads within the array of bonding heads 124. FIG. 2 includes an exploded, cross-sectional view of a portion of the bonding head 224, FIG. 3 includes a cross-sectional view of the portion of the bonding head 224 when assembled, and FIG. 4 includes a bottom view of a mesa 2434, lands 2452 and 2454, zones 2465 and 2469, and ports for a flow channel 2435 coupled to the zone 2465 and a flow channel 2439 coupled to the zone 2469.

The bonding head 224 includes a bonding head body 2412, a sealing member 2422, and a die chuck 2430. The die chuck 2430 and the bonding head body 2412 can be coupled using a vacuum, an electrostatic charge, an electromagnetic attraction, or the like. The description below addresses a vacuum-based system. An electrostatic and electromagnetic systems are addressed later in this specification.

The bonding head body 2412 has flow channels 2413 that allow a vacuum to hold the bonding head body 2412 and the die chuck 2430 together. The bonding head body 2412 further includes a flow channel 2415 that allows a vacuum to hold a die to the die chuck 2430. The bonding head body 2412 also includes a flow channel 2417 that allows a pressurized gas to bow the die chuck 2430 when the die chuck 2430 and the bonding head body 2412 are coupled together. The bonding head body 2412 further includes a flow channel 2419 that allows a pressurized gas to bow a die when the die and the die chuck 2430 are coupled together.

The bonding head body 2412 can be made of a metal, a metal alloy, a glass, a ceramic, a plastic, a composite, or another suitable material. A composite material is a material made out of two or more materials. A typical composite material can include a fiber like material (glass fiber, carbon fiber, etc.) and a matrix binder (ceramic, polymer, etc.). The flow channels 2413, 2415, 2417, and 2419 can be defined by removing portions of the bonding head body 2412 by drilling, cutting, etching, three-dimensional printing, or another suitable technique. Alternatively, material for the bonding head body 2412 can be formed and laterally surround solid objects, such as rods that correspond to the flow channels 2413, 2415, 2417, and 2419. After the shape of the bonding head body 2412 is achieved, the rods can be removed leaving the flow channels 2413, 2415, 2417, and 2419. More or fewer flow channels can be used.

When assembled, as illustrated in FIG. 3, the sealing member 2422 can lie along a peripheral edge of the bonding head body 2412. The sealing member 2422 can perform a function similar to a gasket. Thus, the sealing member 2422 has a relatively large opening in the center that helps to define a pressurization region 3447 that is coupled to the flow channel 2417. The sealing member 2422 includes flow channels 2423, 2425 and 2429. The flow channels 2423 allow a vacuum to hold the die chuck 2430 in place relative to the bonding head body 2412. The flow channel 2425 allows a vacuum to reach a side of the die chuck 2430 to hold a die from the plurality of dies (not illustrated in FIG. 1, 2, or 3). The flow channel 2429 allows a pressurized gas to reach a side of the die chuck 2430 to bow the die while the die is being held by the die chuck 2430.

Referring to FIGS. 2 and 3, the sealing member 2422 can include any of the materials as previously described with respect to the bonding head body 2412. The sealing member 2422 can include an elastomeric material (for example, a silicone, a polybutylene material, or a rubber material). The material for the sealing member 2422 can be the same or different from the bonding head body 2412. Depending on the material of the sealing member 2422, one or more of the previously described techniques with respect to forming the bonding head body 2412 can be used in achieving the shape of the sealing member 2422 as illustrated in FIGS. 2 and 3. The technique to form the sealing member 2422 can be the same or different from the technique used to form the bonding head body 2412. In an implementation, the sealing member 2422 can be a single annular component or may be a set of components, for example a set of O-rings or annular objects.

The die chuck 2430 includes a die chuck body 2432, the mesa 2434, and the lands 2452 and 2454. The die chuck body 2432 can be releasably coupled to the bonding head body 2412. The die chuck body 2432 has a proximal side and a distal side opposite the proximal side, wherein the proximal side of the die chuck body 2432 is disposed between the bonding head body 2412 and the distal side of the die chuck body 2432. The mesa 2434 has a proximal side and a distal side opposite the proximal side, wherein the proximal side of the mesa 2434 is disposed between the die chuck body 2432 and the distal side of the mesa 2434.

Referring to FIGS. 2 to 4, the lands 2452 and 2454 are coupled to the die chuck body 2432 via the mesa 2434. In the same or different implementation, the lands 2452 and 2454 extend from a distal side of the mesa 2434 and are coupled to the die chuck body 2432. The peripheral sides of the mesa 2434 are closer to the land 2452 than to the land 2454. The land 2454 is spaced apart from the land 2452. Each of the lands 2452 and 2454 has a proximal side and a distal side opposite the proximal side, wherein the proximal side of each of the lands 2452 and 2454 is disposed between the mesa 2434 and the distal side of the corresponding land. The zone 2465 is disposed between the lands 2452 and 2454, and the zone 2469 is laterally surrounded by the land 2454.

Surfaces along the distal sides of the lands 2452 and 2454 are chucking surfaces for the die chuck 2430 and substantially co-planar. In an implementation, the surfaces along the distal sides of the lands 2452 and 2454 can lie along planes that are within 5° of being co-planar. The lands 2452 and 2454 may be offset in the Z-axis, such that the distal surface of the land 2452 is at an elevation, as measured in the Z-direction, that is within 7 microns of the elevation of the distal surface of the land 2454. The mesa 2434 of the die chuck 2430 has a chucking area that corresponds to the outer edges of the land 2452 as illustrated in FIG. 4.

A flow channel 2435 can extend from the proximal side of the die chuck body 2432 to the zone 2465 disposed between the lands 2452 and 2454. The flow channel 2435 can be coupled to the flow channel 2425 of the sealing member 2422 and the flow channel 2415 of the bonding head body 2412. A flow channel 2439 can extend from the proximal side of the die chuck body 2432 to the zone 2469. The flow channel 2439 can be coupled to the flow channel 2429 of the sealing member 2422 and the flow channel 2419 of the bonding head body 2412. When a die (not illustrated in FIGS. 2 to 4) lies along one or both of the lands 2452 and 2454, a pressurized gas can be introduced into the zone 2469 and bow a center of the die away from the chucking surface of the die chuck 2430 while a vacuum within the zone 2465 holds the die against the lands 2452 and 2454.

The die chuck 2430 can be formed from a single piece of material or may be formed from at least two different pieces of material. Regarding the latter, the die chuck body 2432 may be formed from one piece of material, and the mesa 2434 and the lands 2452 and 2454 can be formed from another piece of material. The material composition of any or all of the die chuck body 2432, the mesa 2434, and the lands 2452 and 2454 can be any of the materials as previously described with respect to the bonding head body 2412. The bonding head body 2412 can include the same or different material as compared to any or all of the die chuck body 2432, the mesa 2434, and the lands 2452 and 2454. In the same or different implementation, the die chuck body 2432, the mesa 2434, and the lands 2452 and 2454 can include the same material or different materials as compared to one another.

A bonding head within array of bonding heads 124 can be used with a die (that may be a chiplet), wherein the die includes an electrical component, such as a transistor or a capacitor, or a circuit that is sensitive to electrostatic discharge. The electrical component or circuit can be within a microprocessor, a microcontroller, a graphic processing unit, a digital signal processor, a memory die (for example, a Level 2 or Level 3 cache, a flash memory, or the like), a power transistor die, a power circuit die, or the like. The die can be a small block of semiconducting material on which a given functional circuit is fabricated. The die can include a set of electronic components and circuits formed on it by patterning, coating, etching, doping, plating, dicing, etc. The die can have electrical functions, such as the following: memory; logic; field-programmable gate arrays (FPGA); accelerator circuits; application-specific integrated circuits (ASICs); security co-processors; graphics-processing units (GPUs); machine-learning circuits; specialized processors; controllers; devices; electrical circuits; arrays of passive components; etc. The die can also be or include: a micro-electromechanical systems (MEMS) device; an optical device; an electrical-optical device; a microfluidic device; a piezoelectric device; a thermoelectric device; a spintronic device; a superconducting device; etc. The bonding head body 2412, the sealing member 2422, and the die chuck 2430, including the die chuck body 2432, the mesa 2434, and the lands 2452 and 2454, or any combination thereof can include a conductive or static dissipative material.

The material can be present in a sufficient amount to dissipate electrical charge. In an implementation, such material can allow any or all of the bonding head body 2412, the sealing member 2422, and the die chuck 2430, including the die chuck body 2432, the mesa 2434, and the lands 2452 and 2454, to have a resistivity of at most 1×10¹² Ω/square, at most 1×10⁹ Ω/square, or at most 1×10⁶ Ω/square. In the same or different implementation, such material can allow any or all of the bonding head body 2412, the sealing member 2422, and the die chuck 2430, including the die chuck body 2432, the mesa 2434, and the lands 2452 and 2454, to have a resistivity of at least 1×10⁻³ Ω/square, at least 1×10¹ Ω/square, or at least 1×10⁶ Ω/square. In a particular implementation, such material can allow any or all of the bonding head body 2412, the sealing member 2422, and the die chuck 2430, including the die chuck body 2432, the mesa 2434, and the lands 2452 and 2454, to have a resistivity in a range from 1×10⁻³ Ω/square to 1×10¹² Ω/square, 1×10³ Ω/square to 1×10⁶ Ω/square, or 1×10⁶ Ω/square to 1×10⁹ Ω/square. For example, the bonding head body 2412 can be metallic, and the die chuck 2430 can be a conductive polymer or an insulating polymer mixed with a sufficient amount of carbon so that the mixture of the insulating polymer and carbon has a resistivity as previously described.

FIG. 3 includes an illustration of the assembled bonding head 224 and its connections to components that can be used to change pressures within portions of the bonding head 224. Referring to FIGS. 2 and 3, the flow channels 2413 and 2423 are coupled to a manifold that are parts of a flow channel 3423. A pressure actuator 3433 can be used to evacuate the flow channel 3423. In an implementation, the pressure actuator 3433 can allow the flow channel 3423 to backfill and reach ambient pressure, and in the same or different implementation, the pressure actuator 3433 may allow the flow channel 3423 to reach a positive pressure. Ambient pressure (zero gauge pressure) is the pressure within the bonding apparatus 100 outside of and near the bonding head 224. A vacuum pressure is less than ambient pressure and is a negative gauge pressure, and a positive pressure is higher than the ambient pressure and is a positive gauge pressure. When a pressure is at or near ambient pressure, the pressure may be ambient pressure +/−0.5 N/cm².

The flow channels 2415, 2425, and 2435 are parts of a flow channel 3425. A pressure actuator 3435 can be used to evacuate the flow channel 3425 and the zone 2465. In the same or different implementation, the pressure actuator 3435 can allow the flow channel 3425 and the zone 2465 to backfill and reach ambient pressure, and in the same or different implementation, the pressure actuator 3435 may allow the flow channel 3425 and the zone 2465 to reach a positive pressure.

A pressure actuator 3437 can be used to pressurize the flow channel 3427 and the pressurization region 3447. In the same or different implementation, the pressure actuator 3437 can relieve pressure and allow the flow channel 3427 and the pressurization region 3447 to reach ambient pressure. A pressure sensor 3457 can sense the pressure within the flow channel 3427 and transmit signals to the controller 160 or the local controller.

A pressure actuator 3439 can be used to pressurize the flow channel 3429 and the zone 2469. In the same or different implementation, the pressure actuator 3439 can relieve pressure and allow the flow channel 3429 and the zone 2469 to reach ambient pressure, and in the same or different implementation, the pressure actuator 3439 may allow the flow channel 3429 and the zone 2469 to be under vacuum. The pressure sensor 3459 can sense the pressure within the flow channel 3429 and transmit signals to the controller 160 or the local controller.

Bonding heads within the array of bonding heads 124 can be arranged to have a bonding head pitch along the bridge 120. The bonding head pitch for the array of bonding heads 124 should be the same as the bonding pitch, which is the pitch for bonding sites on the bonding substrate. In practice, the bonding head pitch is usually different from the bonding pitch. A successful die transfer can occur when the difference between the bonding head pitch and the bonding pitch is within an acceptable tolerance.

The maximum allowable tolerance for the difference between the bonding head pitch for the array of bonding heads 124 and the bonding pitch for the bonding sites is less than the maximum allowable tolerance for the difference between the bonding head pitch for the array of bonding heads 124 and the bonding head-matching pitch for the array of die transfer seats 144. The bonding heads within the array of bonding heads 124 are more accurately and precisely placed as compared to the die transfer seats within the array of die transfer seats 144. The positions for the bodies of the bonding heads within the array of bonding heads 124 are typically not changed during a transfer operation and may or may not be changed between transfer operations.

Referring to FIG. 1, the bonding chuck 148 can be coupled to the bonding carriage 146 and has a substrate holding surface facing the bridge 120 or a component coupled to the bridge 120. In an implementation, the bonding chuck 148 is attached to the bonding carriage 146. The bonding chuck 148 can hold a bonding substrate having the bonding sites. The bonding chuck 148 can be a vacuum chuck, a pin-type chuck, a groove-type chuck, an electrostatic chuck, an electromagnetic chuck, or the like. The bonding chuck 148 can be heated, cooled, or both heated and cooled. The bonding chuck 148 can include a heater. In the same or different implementation, a fluid (not illustrated) can flow through the bonding chuck 148 to increase or decrease the temperature of the bonding chuck 148.

Alignment hardware 150 is coupled to the bonding carriage 146, and the reference 126 is coupled to the bridge 120 and includes one or more alignment marks. The alignment hardware 150 can include an optical component and provide information to the controller 160 or a local controller located within the alignment hardware 150, the bonding carriage 146, the base 140, or a combination thereof. The alignment hardware 150 can be used to align the bonding carriage 146 to the one or more alignment marks of the reference 126, align the bonding carriage 146 to the array of bonding heads 124, or both.

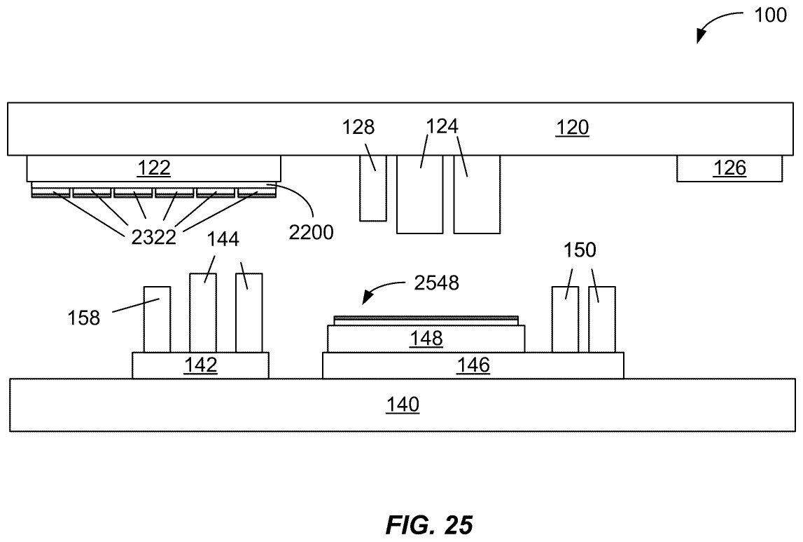

Registration hardware 128 and 158 are coupled to the bridge 120 and the die transfer carriage 142, respectively. The registration hardware 128 and 158 can include an optical component and provide information to the controller 160 or a local controller located within the registration hardware 128 or 158, the bridge 120, the die transfer carriage 142, the base 140, or a combination thereof. A source substrate, dies coupled to the source substrate, a bonding substrate, or a combination of the foregoing can be registered in their respective stage coordinates before dies are transferred from the source substrate to the bonding substrate. The information from the registration hardware 158 can be used to determine the source pitch for the plurality of dies 2322 (illustrated in FIG. 25). Further, the information may be used to identify or confirm the plurality of dies 2322 are the correct dies being transferred. The information from the registration hardware 128 can be used to determine the bonding pitch for the bonding sites of the bonding substrate 2548 (illustrated in FIG. 25). Further, the information may be used to identify or confirm the bonding substrate 2548 is the correct substrate to which dies will be transferred and the position of placement locations for those dies on the bonding substrate 2548.

Returning to FIG. 1, the bonding apparatus 100 can be controlled by the controller 160 in communication with the bridge 120, any component coupled to the bridge 120, the base 140, any component coupled to the base 140, or a combination thereof. The controller 160 can operate using a computer readable program, optionally stored in memory 162. The controller 160 can include a processor (for example, a central processing unit of a microprocessor or microcontroller), a field-programmable gate array (FPGA), an application specific integrated circuit (ASIC), or the like. The controller 160 can further include internal memory, such as a set of registers, a cache memory, a flash memory, or the like. The controller 160 can be within the bonding apparatus 100. In another implementation (not illustrated) of the bonding apparatus, the controller 160 can be at least part of a computer external to the bonding apparatus 100, where such computer is bidirectionally coupled to the bonding apparatus 100. The controller 160 can include one processor or a plurality of processors that communicate over a bus, a local area intranet, or a wide area internet.

The memory 162 can include a non-transitory computer readable medium that includes instructions to carry out the actions associated with the transfer operation. In another implementation, the bridge 120, a component coupled to the bridge 120, the base 140, or a component coupled to the base 140 can include a local controller that provides some of the functionality that would otherwise be provided by the controller 160.

The bonding apparatus 100 can be modified and still achieve many of the benefits as described herein. As previously described, the die chuck 2430 can be retained by using a vacuum. FIG. 5 illustrates another implementation in which a die chuck 5430 can be releasably coupled to a bonding head body 5412, where releasably coupling can involve an electrical charge or electromagnetism. The die chuck 5430 includes a die chuck body 5432 that is similar to the die chuck body 2432. The bonding head body 5412 is similar to the bonding head body 2412 previously described. The flow channel 3423, including flow channels 2423, and the pressure actuator 3433 (illustrated in FIG. 3) are not used with the implementation illustrated in FIG. 5. A sealing member may or may not be disposed between the bonding head body 5412 and the die chuck 5430.

Coupling components 5422 and 5424 can be along or near surfaces of the bonding head body 5412 and the die chuck body 5432, respectively. If any or all of the coupling components 5422 and 5424 are spaced apart from the contacting surfaces between bonding head body 5412 and the die chuck body 5432, such coupling components are sufficiently close to allow the bonding head body 5412 and the die chuck body 5432 to be held together.

The coupling component 5422 can be actuated by a circuit that allows current to flow to the coupling component 5422. The circuit can be controlled by the controller 160 or a local controller. When activated, the circuit allows current to flow to the coupling component 5422 and generate an electrical charge or a magnetic field, and the coupling component 5424 can be attracted to the die chuck 5430 and be retained by the electrical charge or the magnetic field. The coupling component 5422 can include an electrically conductive material, such as a metal or an alloy including the metal. The coupling component 5424 can include a metal or an alloy including the metal. If a magnetic field is used to retain the die chuck 5430, the coupling component 5424 can include a ferromagnetic material.

In another implementation, more lands and zones may be used. As the number of lands and zones increase, a greater variety of die sizes may be used with a bonding head within the array of bonding heads 124. Different types of dies can vary greatly in their X-direction and Y-direction dimensions. For example, a microprocessor may have an X-direction dimension or a Y-direction dimension that is greater than 3.5 cm, a chiplet may have an X-direction dimension and a Y-direction dimension that are each less than 0.5 cm, and a memory die may have an X-direction dimension and a Y-direction dimension that are each in a range of 0.5 cm to 3.5 cm.

The chiplet can be a die that has a component or a circuit that would occupy a significant amount of area, complicate a layout of a conduction path, cause too much capacitive or inductive coupling, or add an additional interconnect (wiring) level if the component or circuit would have been integrated into a die serving a different principal function, such as a microprocessor, a microcontroller, a graphic processing unit, a digital signal processor, or the like. A chiplet can provide a support function for another die and has a component or circuit that, from a timing standpoint, is static or operates at a frequency that is at least an order of magnitude less than a processor on the other die. The chiplet can help to reduce the size, simplify the layout, reduce parasitic capacitive or inductive coupling, reduce the number of interconnect levels, or a combination thereof within a microprocessor, a microcontroller, a graphic processing unit, a digital signal processor, or the like. In an implementation, a chiplet can be a capacitor having electrodes electrically coupled to power supply terminals (e.g., V_{DD} and V_{SS}) of the other die (for example, a microprocessor). In another implementation, the chiplet can be an energy converter, such as a buck converter used to step down a higher direct current voltage (for example, 12 VDC) to a lower direct current voltage (for example, 1 VDC), where the output of the energy converter is used by the other die (for example, a microprocessor).

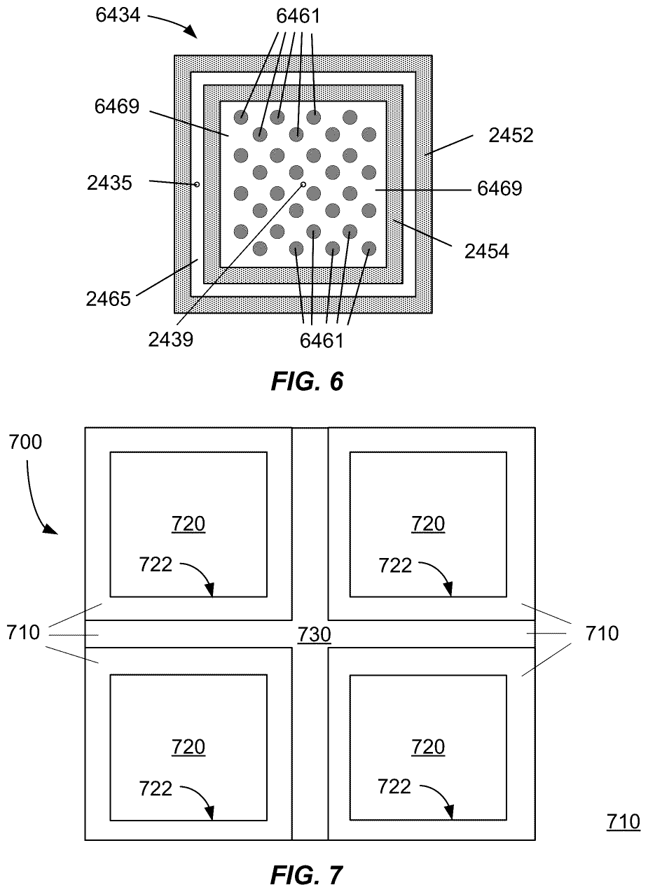

FIG. 6 illustrates another implementation where pins are used. A mesa 6434 is identical to the mesa 2434 as illustrated in FIG. 4 except that a zone 6469 includes pins 6461 that extend from the mesa 6434 to distal surfaces that are seen in FIG. 6. The pins 6461 can help a die from being pulled too far into the zone 6469. For example, the zones 2465 and 6469 can be evacuated when a die is being transferred to the bonding head. The pins 6461 can help to limit how far the die can move into the zone 6469. In the same or different implementation, the pins 6461 may help to more uniformly distribute the downward force applied to a die when the die is being bonded to a bonding substrate.

Distal surfaces of the pins 6461 and the lands 2452 and 2454 can be substantially co-planar. In an implementation, the surfaces along the distal surfaces of the pins 6461 and distal sides of the lands 2452 and 2454 can lie along planes that are within 5° of being co-planar. The pins 6461 and the lands 2452 and 2454 may be offset in the Z-axis, such that the any or all distal surfaces of the pins 6461 are at an elevation, as measured in the Z-direction, that is within 7 microns of the elevation of the distal surfaces of the lands 2452 and 2454. In another implementation, the pins 6461 can extend from the mesa 6434 but may not extend fully to the elevation of the distal surfaces of the lands 2452 and 2454.

For the implementations described herein, each zone can have its own corresponding flow path. The flow path can have an associated pressure actuator that can control the pressure, such as a vacuum, ambient pressure, or a positive pressure (greater than ambient pressure). The pressure actuator can be a valve or a regulator. In an implementation, the pressure actuator can include a combination of valves to allow a zone to be coupled to a vacuum source and a pressurization source. For example, the zone 6469 in FIG. 6 may be evacuated at one point in time during the method, at ambient pressure at another point in time during the method, and at a positive pressure at a further point in time in the method. The pressure actuator for the zone 6469 may be adapted to have at least two valves to achieve the three different pressure states (vacuum, ambient pressure, and positive pressure). Any one or more of the pressure actuators in the apparatus can be controlled by the controller 160 or by a local controller. Pressure information from a pressure sensor can be received by the controller 160 or the local controller, and the controller 160 or the local controller can provide a signal to the corresponding pressure actuator to control the pressure within the flow path or zone.

A vacuum source can be coupled to a zone if the zone is to be evacuated, and a pressurization source can be coupled to a zone if the zone is to be pressurized to a positive pressure. The pressurization source can provide a gas to a zone to be pressurized. The gas can include air, nitrogen, argon, or another gas that is relatively inert to materials within the bonding head, the die, and the bonding substrate.

The shapes of the lands 2452 and 2454 are illustrated in FIGS. 4 and 6 as being square from a bottom view of the mesa. In another implementation, the mesa can have another polygon shape, such as a rectangle (not including a square), a pentagon, a hexagon, an octagon, or the like. In further implementation, the mesa can have a circular shape or an oval shape.

The outermost lands are illustrated as having sides that are coterminous with the lateral sides of their corresponding mesas. In another implementation, the outermost land can be offset from one or more of the lateral sides of its corresponding mesa.

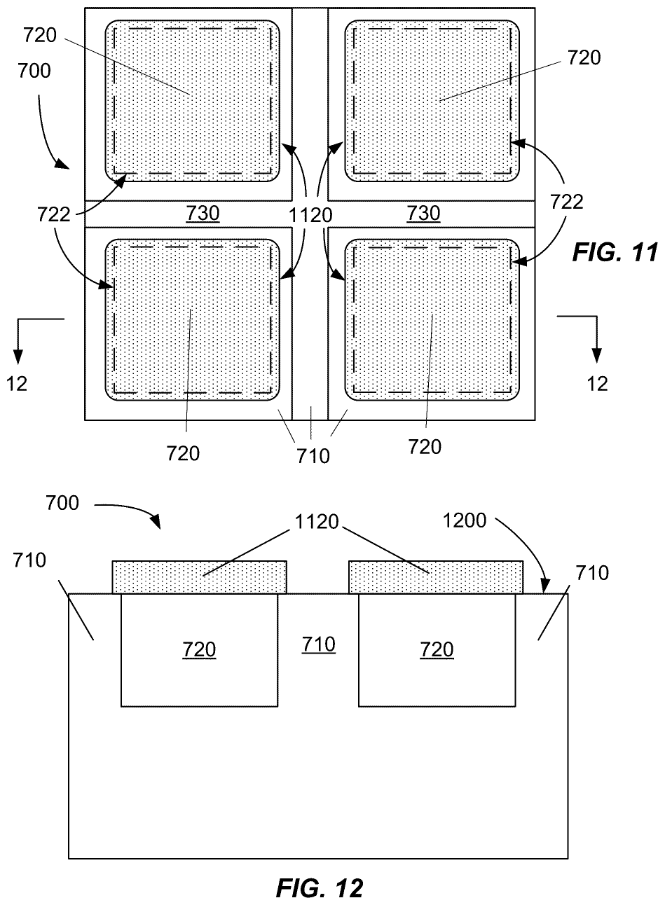

Attention is directed to methods of preparing dies for transferring the dies and using the bonding apparatus 100 when transferring a set of dies from a source substrate to bonding sites on a bonding substrate. FIGS. 8 to 10 include a process flow diagram of a method that is described with respect to FIGS. 11 to 14 and 18 to 35. Some of the figures will be described with respect to a particular die within a set of dies and a particular bonding head within the array of bonding heads 124 to simplify understanding of the methods. Such description also applies to the other dies within the set of dies and the other bonding heads within the array of bonding heads 124. The methods will be described in reference to the bonding apparatus 100 and its components as illustrated in FIGS. 1 to 4 unless explicitly stated to the contrary. After reading this specification, skilled artisans will appreciate that the methods can be used with respect to other apparatuses having other bonding heads as described herein with little or no modification to the methods.

In FIGS. 1, 25 to 28, and 35, the space between (1) the bridge 120 and components coupled to the bridge 120 and (2) the base 140 and components coupled to the base 140 is greatly exaggerated to allow reference numbers and corresponding lead lines to be easier to see. In practice, the bridge 120 and base 140 may be significantly closer to each other than as illustrated. In many of the figures, some illustrated dimensions are exaggerated to improve understanding of features described herein. In FIGS. 12, 13, 18, 20 to 23, and 29 to 34, the thickness of the workpiece relative to the lateral dimensions (measured in a direction perpendicular to the thickness) are thicker than in practice. Other items within the figures may likewise use exaggerated dimensions to illustrate the features of the methods and bonding apparatuses described herein.

The method is described with respect to a workpiece 700, a portion of which is illustrated in the top view in FIG. 7. The workpiece 700 can be fabricated using a semiconductor material. The workpiece 700 can include electronic component regions 720 that can include an electrical circuit element, an optical element, a microelectromechanical system (MEMS), a recording element, a sensor, a mold, an integrated circuit, a power transistor, a charge coupled-device (CCD), an image sensor, or the like. The integrated circuit may be a solid state memory (such as a dynamic random access memory (DRAM), a static random access memory (SRAM), a flash memory, and a magnetoresistive memory (MRAM)), a microprocessor, a microcontroller, a graphics processing unit, a digital signal processor, a field programmable gate array (FPGA) or a semiconductor element, or the like. The electronic component regions 720 can be within guard rings 722 that help to keep contaminants and impurities from entering the electronic component regions 720. With respect to dies, no electrically functional component for a die is located outside its corresponding guard ring 722. The guard rings 722 are illustrated with corners at right angles. In another implementation, the guard rings 722 may be chamfered or slightly rounded at the corners.

The workpiece 700 further includes buffer regions 710 that are between the guard rings 722. The buffer regions 710 can include dicing lanes 730 that may or may not include test structures and correspond to areas where the workpiece will be subsequently diced into dies. The buffer regions 710 may include portions of the workpiece outside the dicing lanes 730.

Attention is directed to methods of preparing dies and using the bonding apparatus 100 when transferring a set of dies to bonding sites of a bonding substrate. The method can include forming a mask over electronic components at block 822 in FIG. 8. FIGS. 11 and 12 include a top view and a cross sectional view of the workpiece 700 after forming a mask, including mask members 1120, over electronic components within the electronic component regions 720 that lie within the dashed lines in FIG. 11. The mask members 1120 extend beyond the guard rings 722 and into the buffer regions 710. The mask members 1120 may be spaced apart from the dicing lanes 730 or may extend into but not completely across any of the dicing lanes 730. As an example, a guard ring 722 and its corresponding dicing lane 730 may be spaced apart by a particular distance, and the mask member 1120 may extend in a range from 2% to 100% of the particular distance from the guard ring 722 toward the corresponding dicing lane 730. In another example, the mask member 1120 may extend into the dicing lane 730; however, a subsequently-defined first edge or a second edge may not properly serve its purpose if a later-formed outer peripheral edge of a die is too close to the die-side edge of the first edge or the second edge. The mask members 1120 can have rounded corners as illustrated in FIG. 11. The significance of the rounded corners is addressed later in this specification.

The electronic component regions 720 may extend from a major surface along a device side 1200 of the workpiece 700 to a depth in a range from 2 microns to the entire thickness of the workpiece. In a non-limiting example, the electronic component regions 720 may include through-substrate vias (TSVs) and extend 50 microns to 95 microns into the workpiece. During a subsequent back side removal to thin the workpiece, the TSVs can become exposed along a back side of the workpiece 700. In another example, the electronic component regions 720 may include a capacitor that has one electrode electrically coupled to a V_{DD} terminal and the other electrode can be electrically coupled to a V_{SS} terminal. For this example, the electronic component regions 720 can be substantially shallower and may extend in a range of 0.2 micron to 9 microns into the workpiece 700. In a further example, the electronic component regions 720 can include a power transistor, and the electronic component regions 720 may extend through the entire thickness of the workpiece 700. In another example, the electronic component regions 720 may include logic circuits, such as for a microprocessor, a microcontroller, a Level 3 cache, or the like. For such an example without TSVs, the electronic component regions 720 may extend in a range from 0.5 microns to 20 microns into the workpiece 700. The examples presented above are meant to illustrate and not limit the range of depths of the electronic component regions 720 that can be used. Depths outside the ranges described above may be used for a particular application.

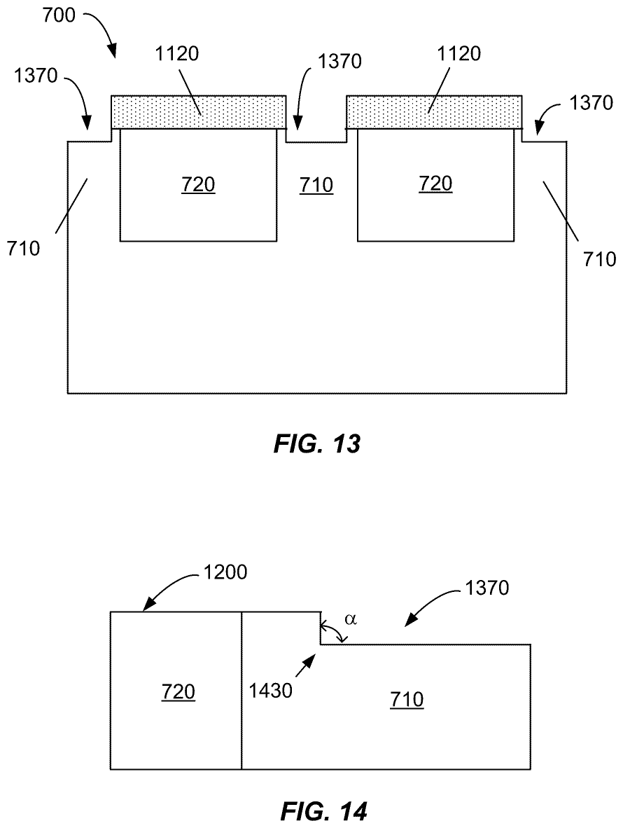

The method can further include creating first edges in a workpiece that includes dies and dicing lanes adjacent to the dies at block 824 in FIG. 8. FIG. 13 includes a cross-sectional view after creating the first edges 1370. In a non-limiting implementation, the first edges 1370 can be created by etching exposed portions of a workpiece within a buffer region along a device side of the workpiece. At this point in the method, the first edges 1370 have shapes that corresponds to recessions or trenches within the workpiece 700. The first edges 1370 have a depth that is sufficient to prevent or reduce substantially the likelihood that a subsequently-formed outer peripheral edge contacts a die chuck or a bonding site during a bonding operation where the die may or may not be bowed during the bonding operation. The depth of the first edges 1370 may be at least 0.1 micron, at least 0.3 micron, or at least 0.5 micron. The first edges 1370 may be relatively deep, such as 50 microns; however, such a depth is not needed and may adversely affect equipment throughput. Further, if the etching has significant lateral etching (in a direction parallel to the major surface), the etch may remove portions of layers that overlap or underlap the guard rings 722 (illustrated in FIG. 11) or remove portions of the guard rings 722 if the etching is performed too long. Thus, the first edges 1370 may have depths that are at most 20 microns, 9.0 microns, or 3.0 microns. The first edges 1370 can have depths in a range from 0.1 micron to 20 microns, 0.1 micron to 9.0 microns, or 0.1 micron to 3.0 microns.

The mask members 1120 are removed after the first edges 1370 have been created. The first edges 1370 laterally surround mesas that are portions of the workpiece 700 that were covered by the mask members 1120. The sidewalls of the first edges 1370 are also referred to as mesa edges for the mesas. The mesas lie at elevations above the bottoms of the first edges 1370. Referring to the top view in FIG. 11, the mesas have shapes that correspond to the mask members 1120 used to define the recessions. The rounded corners reduce the likelihood of chipping or fracturing that may occur if sharp corners would have been formed. Thus, trapping particles between the dies and bonding sites during a bonding operation is reduced by using rounded corners as compared to sharp corners.

FIGS. 14 to 17 include cross sectional views of portions of the workpiece that include portions of a mesa and a first edge. In FIG. 14, the first edge 1370 can be formed using an anisotropic etch. The mesa edges of the mesas can be substantially vertical, and angle α can be in a range from 85° to 95°, thus, the corner 1430 can be at or near a right angle. A deeper first edge 1370 can be formed with no or an insubstantial likelihood of reaching the guard ring during the etch. Furthermore, the sidewall as illustrated in FIG. 14 can be helpful to make alignment to the mesas easier.

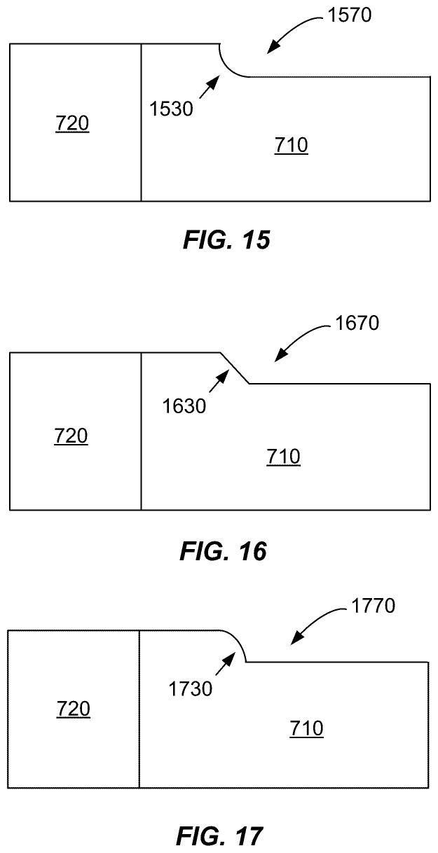

FIG. 15 illustrates a first edge 1570 with a mesa having a curved sidewall 1530. An isotropic etch can be performed to achieve the curved sidewall 1530. FIG. 16 illustrates a first edge 1670 with a mesa having a sidewall 1630 to produce a chamfered shape. A portion of the mask member (not illustrated) can be etched when the workpiece is being etched. For example, the etch can be performed using an anisotropic etchant for the workpiece and an isotropic etchant for the mask member. The slope of the chamfered sidewall 1630 can be controlled by adjusting the relative etch rates for the mask member and the workpiece. FIG. 17 illustrates a first edge 1770 with a mesa having a sidewall 1730 has an arc shape that rises asymptotically from the bottom of the first edge 1770 to the top of the mesa. Care may need to be exercised when defining the first edges 1570, 1670, and 1770 to ensure the first edges do not laterally extend to the guard rings and corresponding electronic component regions 720.

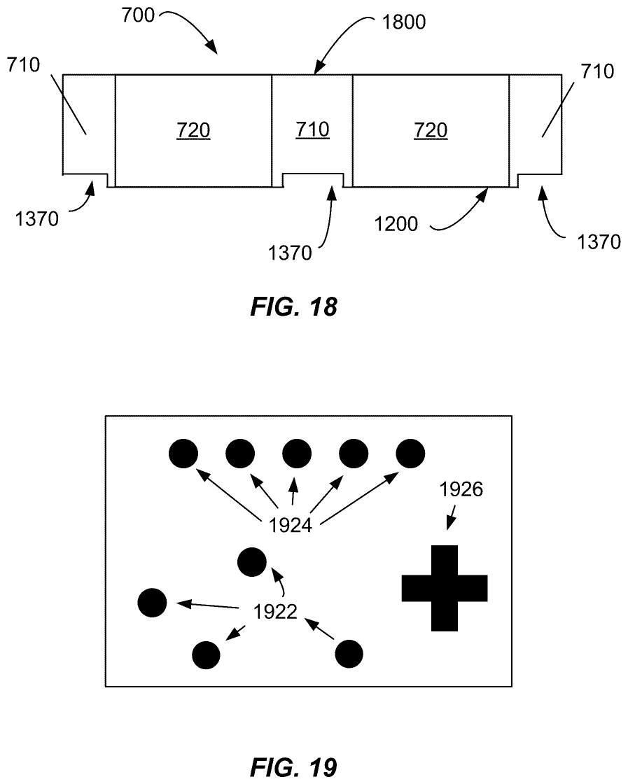

The method can include backgrinding or lapping a back side of the workpiece at block 842 in FIG. 8. FIG. 18 illustrates the workpiece 700 after turning the workpiece 700 over and backgrinding or lapping a back side 1800 of the workpiece 700. The backgrinding or lapping may be performed before reaching the electronic component regions 720 or when or after reaching the electronic component regions 720 as illustrated in FIG. 18. When the electronic component regions 720 include TSVs, the TSVs can become exposed as illustrated in FIG. 19. TSVs 1922 can be made to electric circuit elements or circuits, where the TSVs 1922 may or may not be part of a pattern. TSVs 1924 may be part of a pattern that may, for example, correspond to address pins for a memory. A difference is that the TSVs 1924 can be characterized by a pitch, and the TSVs 1922 may not. An optional alignment feature 1926 may be formed when forming the TSVs 1922 and 1924. In another implementation, the alignment feature 1926 may not be formed. If the electronic component regions 720 did not have any TSVs and alignment features, the back side 1800 may not have any features exposed.

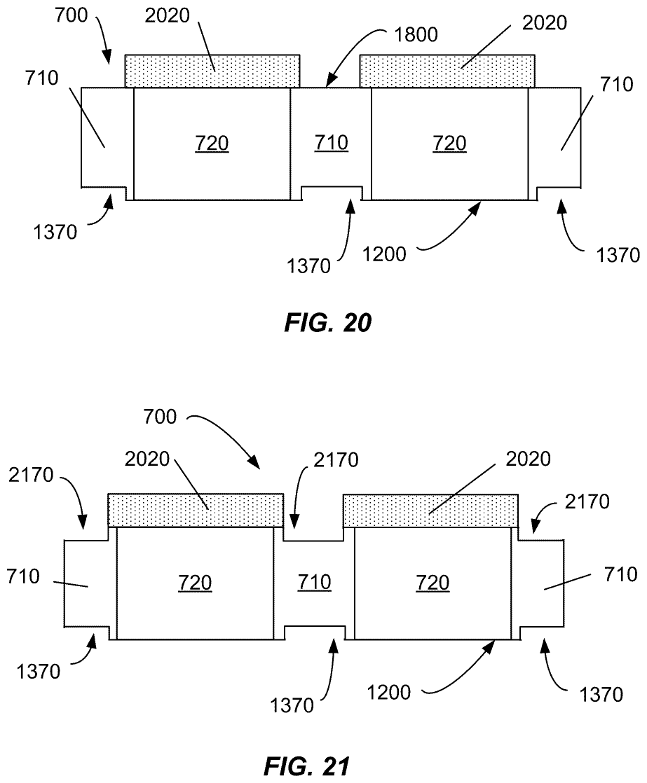

The method can include forming a mask along a back side of the substrate corresponding to the electronic components at block 862 in FIG. 8. FIG. 20 includes a cross-sectional view of the workpiece 700 after forming the mask members 2020 along the back side surface 1800. The mask, including the mask members 2020, can be aligned to a location of the workpiece 700. The mask can be aligned to the alignment feature 1926 or any one or more of the TSVs 1922 and 1924 as illustrated in FIG. 19. In another implementation, radiation may be emitted through the workpiece 700 and is received by a radiation detector. The radiation detector can provide signals to a computer or controller than can process the signals to generate an image from which alignment to features along the device side. In a further implementation, alignment may be performed using self-aligning bonding by hydrophilic contrast as described in US Patent Publication No. US 2023/0420408. The mask does not need to be perfectly aligned, and misalignment of 1 micron may not be a problem. The placement of the mask with the mask members 2020 is similar to the placement of the mask with the mask members 1120. The electronic component regions 720 and part of the buffer region 710 are covered by the mask members 2020.

The method can further include creating second edges in the workpiece at block 864 in FIG. 8. FIG. 21 includes a cross-sectional view of the workpiece 700 after creating the second edges 2170. In a non-limiting implementation, creating the second edges can be performed by etching exposed portions of a workpiece within a buffer region along a back side of the workpiece. At this point in the method, the second edges 2170 have shapes that corresponds to recessions or trenches within the workpiece 700. The second edges 2170 can have any of the design considerations, dimensions, and formation techniques as previously described with respect to the first edges 1370. The second edges 2170 may have the same or different design considerations, dimensions, and definition techniques as compared to the first edges 1370. Referring to FIG. 21, at least part of the second edges 2170 overlap at least part of corresponding first edges 1370, and at least part of the first edges 1370 underlap at least part of the second edges 2170. In another implementation, the second edges 2170 may have a shape similar to shapes illustrated in FIGS. 15 to 17. The mask members 2020 are removed after the second edges 2170 are defined.

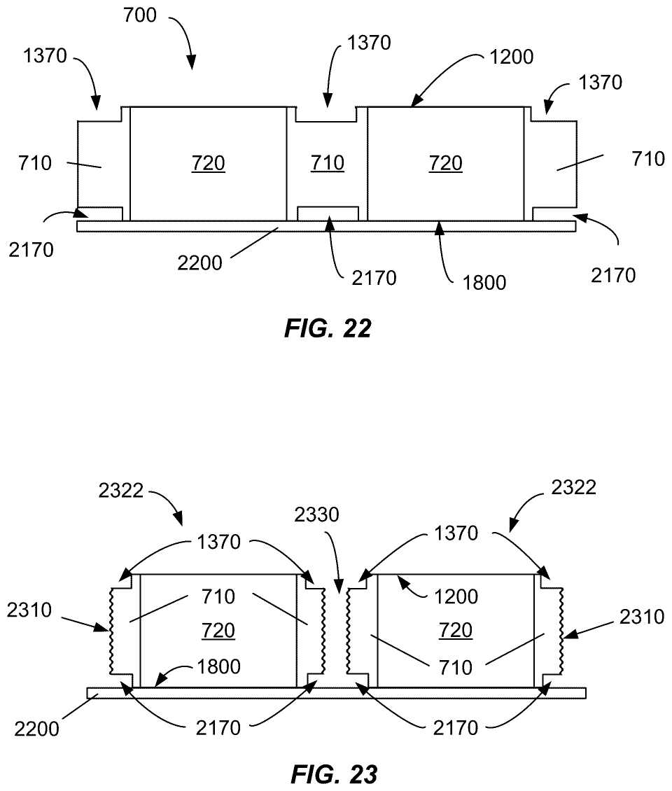

The method can include dicing the workpiece along dicing lanes to produce a plurality of dies at block 866 in FIG. 8. In the implementation illustrated, the device sides 1200 of dies from the workpiece 700 will be bonded to bonding sites of a bonding substrate. The workpiece 700 is turned over and attached to a source substrate that can be tape 2200 in the implementation illustrated in FIG. 22. In another implementation, the source substrate can be an adhesive tape that may be in the form of a tape frame or a tape reel, a container having a lattice that defines a matrix of regions that can hold the plurality of dies 2322, or the like. If the back sides 1800 of the dies from the workpiece 700 are to be bonded to the bonding sited, the workpiece 700 may not be turned over.

The workpiece 700 can be diced along the dicing lanes 730 (illustrated in FIG. 11) to form a plurality of dies 2322 as illustrated in FIG. 23. The plurality of dies 2322 are separated by gaps 2330. Dicing can be performed using a saw, a water jet, stealth dicing, or another mechanical tool. Dicing forms outer peripheral edges 2310 that are substantially rougher than the surfaces associated with the first edges 1370, the second edges 2170, or both sets of edges. The outer peripheral edges 2310 are a specific type of outer peripheral edges. The dicing causes crystal defects to form along and particles to be generated from the outer peripheral edges 2310. More particles are dislodged or generated when handling the dies or as an object contacts the outer peripheral edges 2310 of the dies. The first and second edges 1370 and 2170 reduce the likelihood of contact, and thus, less particles are dislodged or generated and trapped between the dies 2322 and the bonding sites during bonding operations.

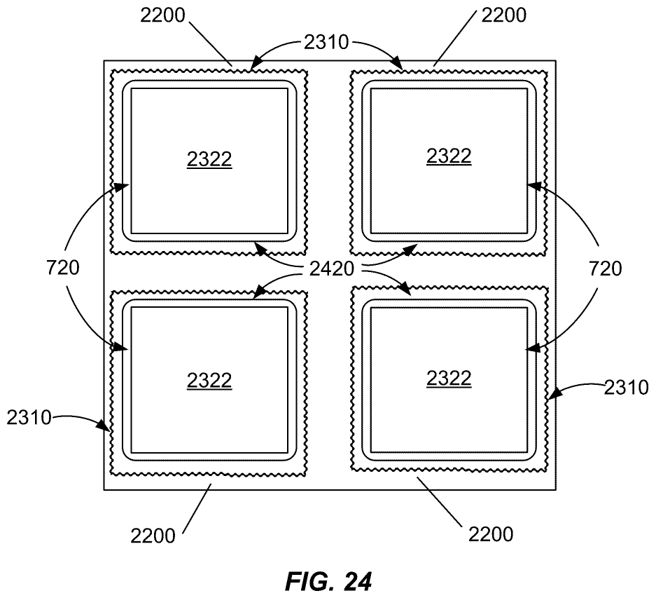

FIG. 24 includes a top view of the plurality of dies 2322 after dicing. The mesas have rounded corners along their mesa edges 2420. The rounded corners can help to reduce stress along the corners and reduce the likelihood of particle generation. As compared to a sharp corner, the rounded corner will better distribute the loading, which lowers the stress. The relatively smoother surfaces along the mesa edges 2420 and the portions of the first edges closer to the mesa edges, as compared a die with no first edge, can help to ensure a higher quality of bonding.

The plurality of dies 2322 and a bonding substrate can be prepared such that the dies, the bonding substrate, or both have activated surfaces to aid in bonding. After cleaning, a surface can be activated by exposing the surface to a plasma treatment and deionized water rinse to hydrate the surface. Where reasonably practical, contact with an activated surface before bonding should be avoided. In FIGS. 25 to 38, activated surfaces of the dies and bonding substrate are illustrated as dark bands where bonding can occur. Although not illustrated, part or all of the exposed surfaces of the first and second edges 1370 and 2170 and outer peripheral edges 2310 can be activated. The surfaces can be activated before the source substrate and bonding substrate are mounted to their corresponding substrate chuck 122 and bonding chuck 148. With respect to the workpiece 700 and the plurality of dies 2322, activation can be performed after creating the first and second edges 1370 and 2170 and before the source substrate, which is the tape 2200 in a particular implementation, is mounted to the source chuck 122. Thus, the activation can be formed at a time that is well suited for a particular application.

In FIGS. 25 to 28 and 35, the controller 160 and the memory 162 (illustrated in FIG. 1) are present but are not illustrated to simplify understanding of operations associated with the bonding apparatus 100.

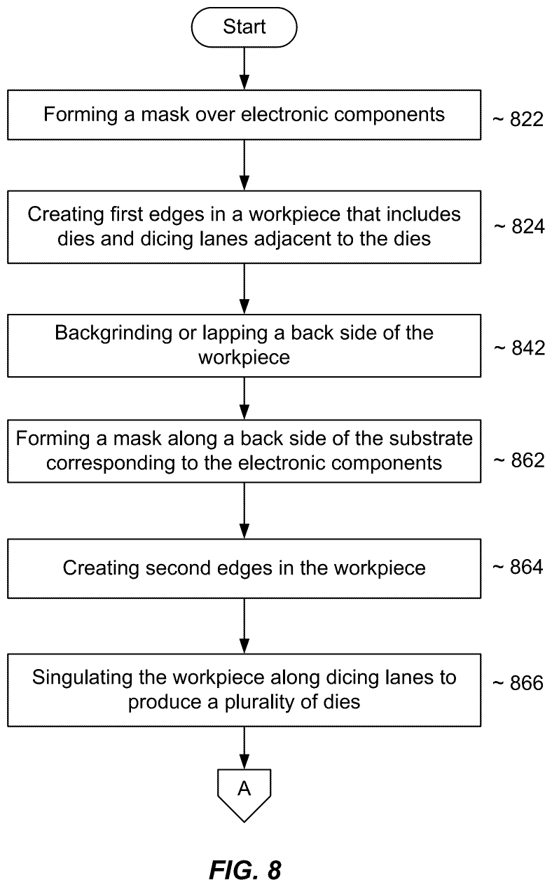

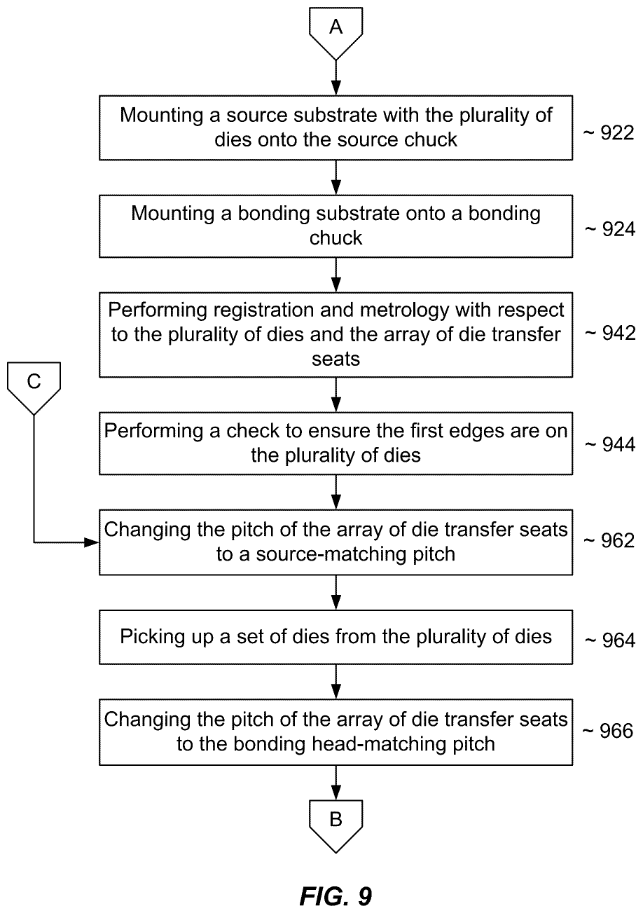

The method can include mounting a source substrate with the plurality of dies onto the source chuck at block 922 and mounting a bonding substrate onto a bonding chuck at block 924 in FIG. 9. As illustrated in FIG. 25, the die transfer carriage 142 and the bonding carriage 146 may be moved to allow easier access to the source chuck 122 and bonding chuck 148. The actions in blocks 922 and 924 can be performed in either order. The plurality of dies 2322 are attached to the tape 2200 that is the source substrate in the implementation illustrated. A bonding substrate 2548 can include any of the substrates described with respect to the source substrate and can also include a semiconductor wafer, a package substrate, a printed wiring board, a circuit board, an interposer, or the like. Microelectronic devices may be part of the bonding substrate 2548, such as a semiconductor wafer. The package substrate, the printed wiring board, the circuit board, or the interposer may or may not have dies mounted thereto. Part or all of the side of the bonding substrate 2548 can be activated for hybrid bonding.

The method can include performing registration and metrology with respect to the plurality of dies and the array of die transfer seats at block 942 in FIG. 9. The registration hardware 158 can pass under the source chuck 122 while the source substrate and the plurality of dies 2322 are coupled to the source chuck 122. Information from the registration hardware 158 can be transmitted to the controller 160 or a local controller and used to determine the source pitch for the plurality of dies 2322. The registration hardware 128 can pass over the bonding chuck 148 while the bonding substrate 2548 is coupled to the bonding chuck 148. Information from the registration hardware 128 can be transmitted to the controller 160 or a local controller and used to determine the bonding pitch for the bonding sites of bonding substrate 2548 and locations of the bonding sites. If needed or desired, the information may be used to identify or confirm the plurality of dies 2322 and the bonding substrate 2548 are the correct dies and the correct bonding substrate for bonding.

The method can further include performing a check to ensure the first edges are on the plurality of dies at block 944 in FIG. 9. The registration hardware 158 can pass under the source chuck 122 while the source substrate and the plurality of dies 2322 are coupled to the source chuck 122. Information from the registration hardware 158 can be transmitted to the controller 160 or a local controller and used to determine whether or not the first edges 1370 are present on the plurality of dies 2322. If the first edges 1370 are present, the method can proceed to the next operation. Otherwise, the plurality of dies 2322 can be removed from the bonding apparatus 100, where the plurality of dies 2322 may be rejected or a remedial measure can be performed to create the first edges 1370 on the plurality of dies 2322. After the first edges 1370 are created, the plurality of dies 2322 can be mounted to the source chuck 122 and the registration and metrology operations described with respect block 942 can be performed.

In a particular implementation where the pitch of the array of die transfer seats 144 is changed during a transfer cycle, the method can further include changing the pitch of the array of die transfer seats to a source-matching pitch at block 962 in FIG. 9. The controller 160 or a local controller can transmit a signal for the die transfer seats within the array of die transfer seats 144 to be adjusted to have the source-matching pitch. The source-matching pitch can be the same or within an allowable tolerance of the source pitch. The source pitch can be an X-direction pitch, a Y-direction pitch, or both for the plurality of dies 2322 attached to the tape 2200. The allowable tolerance may account for a small amount of variation for the manufacturing equipment within the bonding apparatus 100. Such an allowable tolerance may allow the source-matching pitch to be within 10% of the source pitch and can be less than 5% or 1% of the source pitch.

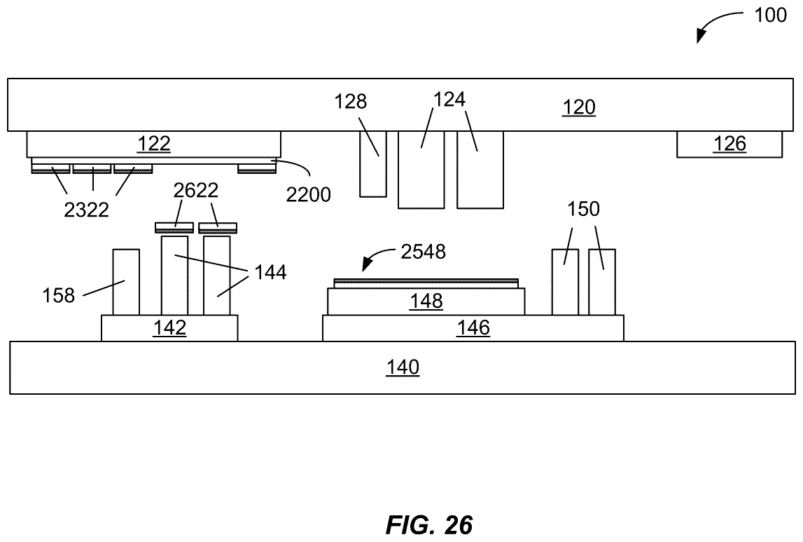

The method can include picking up a set of dies from the plurality of dies at block 964 in FIG. 9. The controller 160 or a local controller can transmit a signal for the die transfer seats within the array of die transfer seats 144 to be extended in the Z-direction and pick up a set of dies 2622 as illustrated in FIG. 26. The dies that are picked up may be dies that are closest to each other, or one or more other dies may be between the picked-up dies, such as illustrated in FIG. 26. Dies that are not picked up remain coupled to the source chuck 122 as illustrated in FIG. 26.

In an implementation, the array of die transfer seats 144 do not contact the activated surfaces of the dies being transferred. The die chucks for the array of die transfer seats 144 can have a design that allows dies to be picked up along side surfaces of the dies, where the side surfaces are between the device and back sides of the dies. In another implementation, the array of die transfer seats 144 can include Bernoulli chucks.

In another implementation, the source chuck 122 may not be present and the set of dies 2622 can be transferred to the array of die transfer seats 144 by a placement tool or an operator. The array of die transfer seats 144 may be at a pitch or otherwise positioned to allow the placement tool or operator to reproducibly place dies on the array of die transfer seats 144. The subsequent description is based the bonding apparatus 100 that has the source chuck 122 with the source substrate coupled to the source chuck 122.

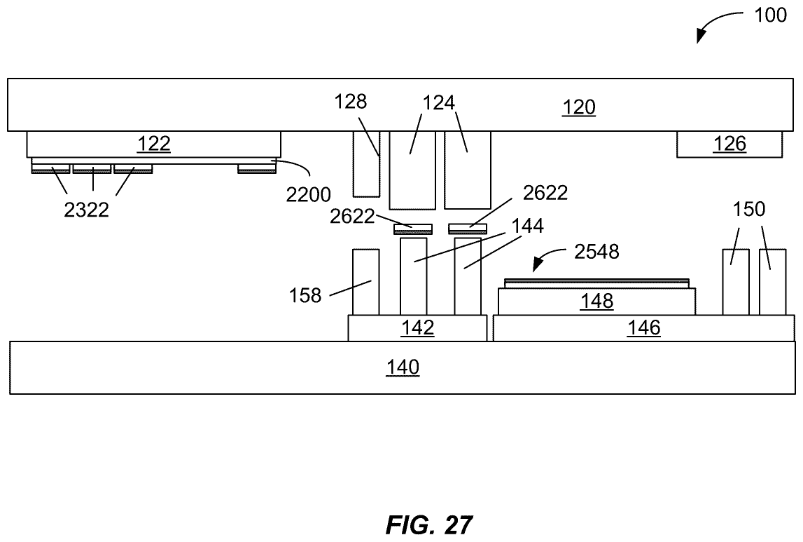

The method can further include changing the pitch of the array of die transfer seats to the bonding head-matching pitch at block 966 in FIG. 9. Referring to FIGS. 26 and 27, the pitch for the array of die transfer seats 144 is changed from the source-matching pitch to the bonding head-matching pitch. The controller 160 or a local controller can transmit a signal for the die transfer seats within the array of die transfer seats 144 to move to achieve the desired pitch. The set of dies 2622 are coupled to the array of die transfer seats 144 when the pitch for the array of die transfer seats 144 is changed. The bonding head-matching pitch for the array of die transfer seats 144 can be the same or within an allowable tolerance of the bonding head pitch for the array of bonding heads 124. Such an allowable tolerance may allow the bonding head-matching pitch to be within 10% of the source pitch and can be less than 5% or 1% of the bonding head pitch.

If the second edges 2170 are on a side of the dies opposite the first edges 1370, the method can include performing a check to ensure second edges 2170 are on the set of dies 2622. The operation is similar to the operation described with respect to block 944. The check for the second edges 2170 can be performed after the set of dies 2622 are transferred to the array of die transfer seats 144 and before transferring the set of dies 2622 to the array of bonding heads 124.

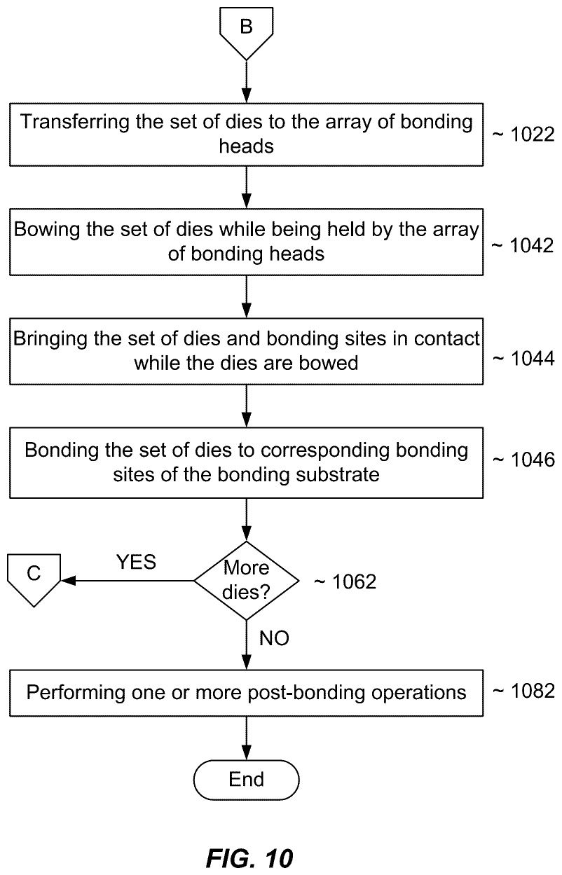

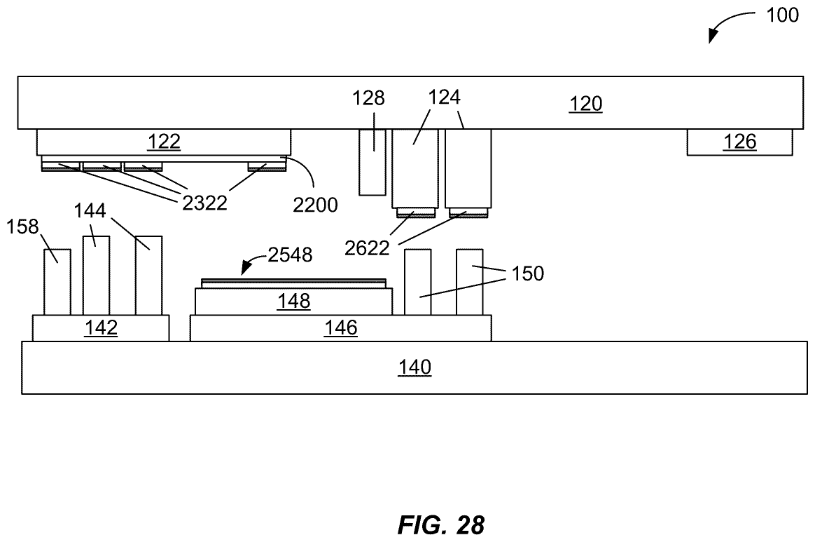

The method can include transferring the set of dies to the array of bonding heads at block 1022 in FIG. 10. Referring to FIGS. 27 and 28, the die transfer carriage 142 and bonding carriage 146 are moved to the right. The die transfer carriage 142 is moved so that the array of bonding heads 124 is over the array of die transfer seats 144. If needed or desired, the registration hardware 128, 158, or both can be used to confirm the array of die transfer seats 144 is properly positioned with respect to the array of bonding heads 124. The controller 160 or a local controller can transmit a signal for the die transfer seats within the array of die transfer seats 144 to be extended toward the bonding heads within the array of bonding heads 124, for the bonding heads within the array of bonding heads 124 to be extended toward the die transfer seats within the array of die transfer seats 144, or both.

Referring to FIGS. 1, 3, and 4, the controller 160 or a local controller can transmit a signal for the pressure actuator 3435 for the bonding head 224 to activate the pressure actuator 3435 to evacuate the flow channel 3425 and the zone 2465. The vacuum within the zone 2465 can be sufficient to hold a die within the set of dies 2622. The zone 2469 can be at or near ambient pressure or be evacuated similar to the zone 2465. The controller 160 or local controller may or may not transmit a signal to activate the pressure actuator 3439 to achieve the desired pressure (vacuum or at or near ambient pressure) for the zone 2469.

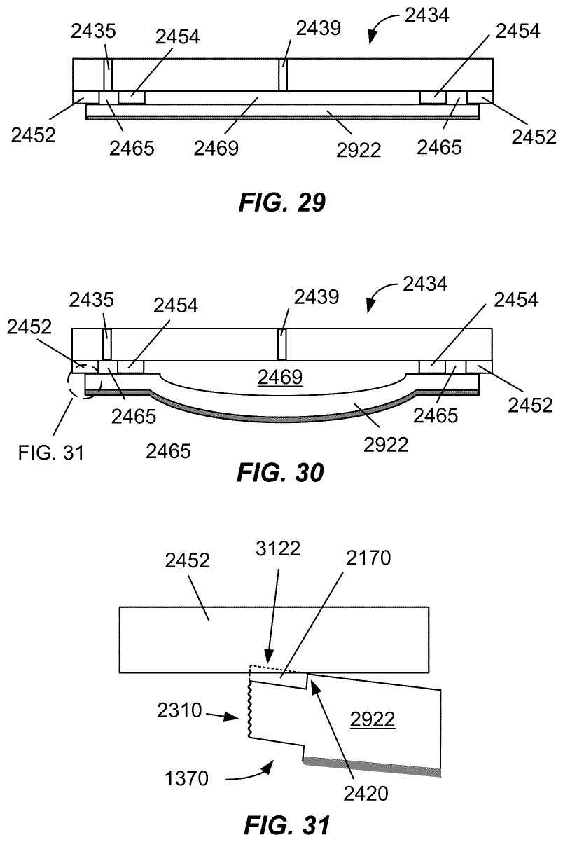

FIG. 28 includes the set of dies 2622 after being transferred from the array of die transfer seats 144 to the array of bonding heads 124. FIG. 29 includes a particular die 2922 within the set of dies 2622 that is held by a particular bonding head within the array of bonding heads 124. FIG. 29 includes many of the features previously described. The die chuck body 2432, the sealing member 2422, the bonding head body 2412, and their corresponding flow channels and actuators for the bonding head are present but are not illustrated in FIGS. 29 to 34 to simplify understanding of the concepts described herein.

The method can further include bowing the set of dies while being held by the array of bonding heads at block 1042 in FIG. 10. Data can be useful in determining how much pressurization should be used. For example, as a die occupies a larger area (X-direction and Y-direction dimensions) and is thinner (Z-direction dimension), less pressure is needed to bow the die as compared to a die that occupies a smaller area, is thicker, or both. If the die is attached to a backing plate, the combined thickness of the die and backing plate can be used when determining the pressure to achieve a desired amount of bowing. The thicknesses of the dies alone or the combinations of dies and their corresponding backing plates can be in a range from 20 microns to 700 microns or from 20 microns to 300 microns. The methods described herein are well suited for thicknesses of at most 100 microns. The data can be obtained for many different die areas and thicknesses. The memory 162 or a table or database external to the bonding apparatus 100 can have data that correlates different areas and thicknesses of the die and the positive pressures or ranges of positive pressures to use to allow for sufficient bowing of the dies. The information can be empirical data collected before using the data in production.

Referring to FIGS. 1, 3, 4, and 30, the controller 160 or a local controller transmits a signal for the pressure actuator 3439 to be activated and allow a pressurized gas to increase the pressure within the flow channel 3429 and the zone 2469. The pressure sensor 3459 can sense the pressure within the flow channel 3429 and transmit signals to the controller 160 or the local controller, so that the controller 160 or the local controller can control the pressure to be at or within acceptable tolerance of a targeted pressure. As the pressure within the zone 2469 increases, the dies bow away from the bonding head within the array of bonding heads 124 and toward the base 140 or the bonding substrate 2548 that is coupled to the base 140 (seen in FIG. 28). FIG. 30 illustrates the particular die 2922, and the other dies within the set of dies 2622 can have a bowed shape similar to the particular die 2922.

FIG. 31 includes a portion of FIG. 30 to illustrate better the relationship between bowing and the second edges 2170. The amount of bowing in FIG. 31 is exaggerated to improve understanding of the concepts. Bowing causes the particular die 2922 to move. With the second edges 2170, the movement caused by bowing helps to keep the outer peripheral edge 2310 of the particular die 2922 from contacting the bonding head. The dashed line 3122 illustrates the shape of the particular die 2922 if the second edges 2170 would not have been present. The part of the particular die 2922 at the outer peripheral edge 2310 would have contacted the bonding head, and due to the roughness of the outer peripheral edge 2310 and a relatively high crystal defect density at and adjacent to the outer peripheral edge 2310, particle dislodging and generation and fracturing are more likely to occur. The mesa edge 2420 contacts the bonding head, and the dimensions of the second edges 2170 (for example, depth and distance between the mesa edge 2420 and the outer peripheral edge 2310) help to keep the outer peripheral edge 2310 from contacting the bonding head during bowing.

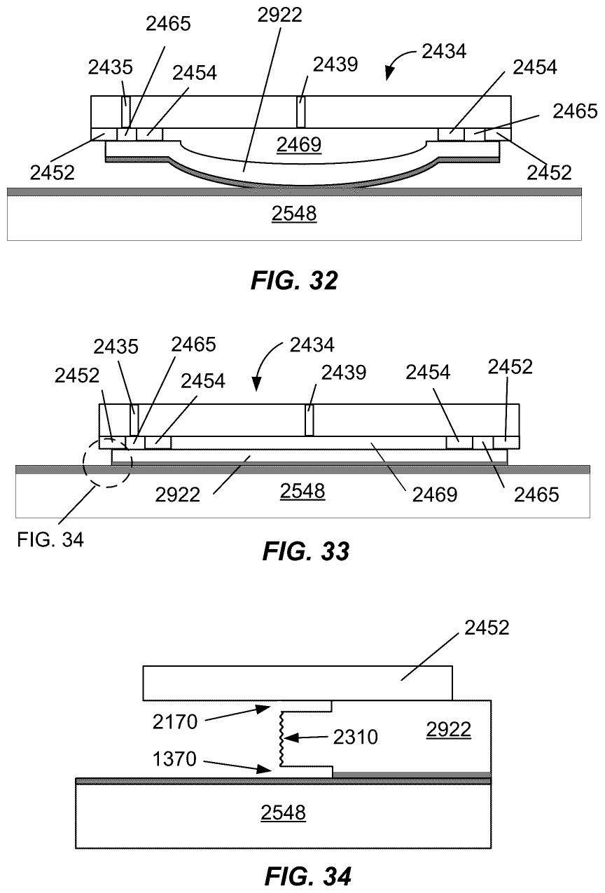

The method can include bringing the set of dies and bonding sites in contact while the dies are bowed at block 1044 in FIG. 10. Referring to FIGS. 1 and 32, the bonding heads within the array of bonding heads 124 can be extended toward the bonding substrate 2548, the bonding chuck 148 can be extended toward the array of bonding heads 124, or both. As illustrated in FIG. 32, the center of the particular die 2922 contacts a bonding site of the bonding substrate 2548 before other portions of the particular die 2922 contact the bonding site. Thus, the likelihood of trapped air between the particular die 2922 and bonding substrate 2548 during bonding is substantially less than if bowing was not performed.

The method can further include bonding the set of dies to corresponding bonding sites of the bonding substrate at block 1046 in FIG. 10 Referring to FIGS. 1, 3, 4, and 33, the bonding heads for the array of bonding heads 124 can be further extended toward the bonding substrate 2548, the bonding chuck 148 can be extended toward the array of bonding heads 124, or both. The amount of bowing can be reduced as contact area between the particular die 2922 and the bonding site of the bonding substrate 2548 increases.

Pressure is exerted to bond the set of dies 2622 to corresponding bonding sites of the bonding substrate 2548. In an implementation, the bonds can be oxide-to-oxide bonds. The pressure during bonding can be in a range from 0.5 N/cm² to 20 N/cm². The controller 160 or a local controller can transmit a signal for a motor, hydraulic pressure, or another mechanical component that can be used to drive the array of bonding heads 124, the bonding chuck 148, or both in the Z-direction to achieve the bonding pressure. Referring to FIGS. 3 and 4, during bonding, if needed or desired, the pressure within the zone 2469 can be at a positive pressure that is at or within a tolerance of the pressures exerted by the motor, the hydraulic pressure, or other mechanical component to allow for more uniform pressure along the surface of the set of dies 2622, including the particular die 2922 illustrated in FIG. 33, during bonding. In another implementation, the pressure within the zone 2469 can be at or near ambient pressure. In the same or different implementation, the pressure within the zone 2465 can remain at vacuum pressure, be at or near ambient pressure, or a pressure that is substantially the same as within the zone 2469.

The bonding can be performed at room temperature (for example, at a temperature in a range from 20° C. to 25° C.) or higher. Bonding is performed at a temperature less than a subsequent anneal to expand conductive metal within the dies and at the bonding sites. The temperature may be limited depending on films present during bonding or components within the bonding apparatus 100. For example, the temperature may be no higher than approximately 200° C. After reading this specification, skilled artisans will be able to determine the pressure and temperature used for bonding.

FIG. 34 includes a cross-sectional view of an enlarged portion of FIG. 33 at a location seen in FIG. 33. Particle generation may be more likely near the outer peripheral edges 2310 as opposed to the electronic component regions 720. In the implementation as illustrated in FIG. 34, the particular die 2922 contacts the particular bonding head within the array of bonding heads 124 and the bonding substrate. More specifically, the particular die 2922 contacts the land 2452 that is part of the die chuck for the bonding head and the bonding site of the bonding substrate 2548. The first edges 1370, the second edges 2170, or the first and second edges 1370 and 2170 help to keep the outer peripheral edge 2310 from contacting any part of the die chuck of the bonding head and the bonding substrate 2548. In reference to the particular die 2922 and other dies within the set of dies 2622, the first edges 1370 can help to reduce the likelihood that particles will be dislodged, generated, trapped, or any combination thereof between the set of dies 2622 and their corresponding bonding sites of the bonding substrate 2548. Similarly, the second edges 2170 can help to reduce the likelihood that particles will be dislodged or generated from the set of dies 2622 with respect to the die chucks within the array of bonding heads 124. Thus, particles are less likely to be trapped between electrical component regions 720 and the bonding sites of the bonding substrate 2548.

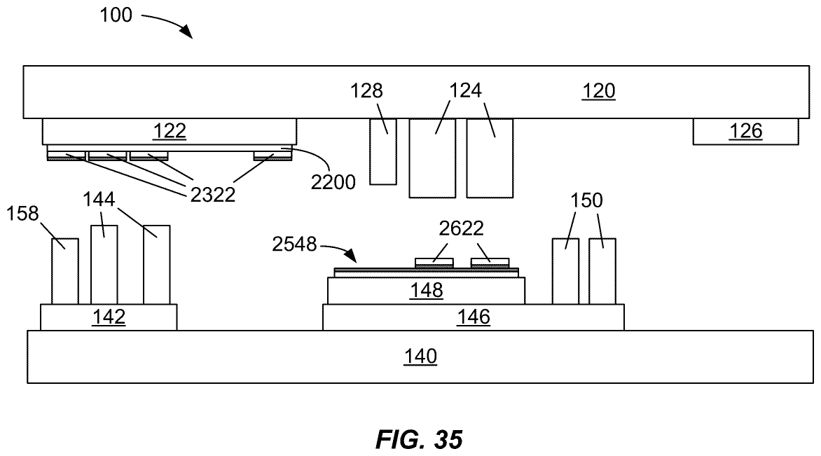

FIG. 35 includes a cross-sectional view of the bonding apparatus 100 after the set of dies 2622 are bonded to corresponding bonding sites of the bonding substrate 2548. At this point in the method, one transfer cycle has been completed.

A determination is made whether more dies are to be transferred from the source substrate to the bonding substrate at decision diamond 1062 in FIG. 10. If more dies are to be transferred (“YES” branch), the method continues starting at block 962 in FIG. 9 with a next set of dies transferred during another transfer cycle. The method can be iterated as many times as needed for the bonding substrate 2548 to have a desired number of dies. If no more dies are to be transferred (“NO” branch from decision diamond 1062 in FIG. 10), the transfer operation is completed.

A hybrid bonding process can include three steps that include a bonding operation, a first anneal to cause the metal within the dies and at the bonding sites to expand and contact each other, and an optional second anneal to cause metal atoms to cross the metal-metal interface and reduce contact resistance. The previously described methods correspond to the bonding operation.

After all of the transfer cycles have been performed and the transfer operation is completed, the bonding substrate 2548 and the corresponding bonded dies can be annealed at a temperature in a range from 180° C. to 400° C. In an implementation, annealing may be performed at one or more temperatures. As the temperature of the conductive metal increases, the conductive metal expands. The conductive metal in electrical components within the bonding substrate 2548 contacts the conductive metal in the bonded dies to make a physical and electrical coupling between the conductive materials. If needed or desired, the anneal temperature can be increased further, so that atoms from the conductive metals can cross the interfaces between the electrical components in the bonding substrate 2548 and the bonded dies and reduce contact resistance. In an implementation, the physical and electrical coupling can be a physical and electrical connection. Thus, the bonded dies and the sets of electrical components in the bonding substrate 2548 can allow voltages to be passed and current to flow between the bonded dies and the sets of electrical components. The bonding substrate 2548 can be removed from the bonding apparatus 100 or moved to a different portion of the bonding apparatus 100 or a different tool to perform the anneal operations.

The method can further include performing one or more post-bonding operations at block 1082 in FIG. 10. Non-limiting examples electrical testing the electronic devices that includes the bonded dies, dicing the bonding substrate into individual electronic devices, cleaning the electronic devices, packaging the electronic devices, performing another suitable post-bonding operation, or the like. The order in which the post-bonding operations may or may not depend on the particular electronic devices. For example, the packaging operation may be performed before or after the dicing operation is performed. Still further, more than one electrical test may be performed at different times where an intervening operation may or may not be performed between the electrical tests. For example, a first electrical test for electrical shorts or electrical opens may be performed before packaging. After packaging, a second electrical test can be performed to test a memory to ensure data can be written and retrieved or a processor to ensure instructions can be performed properly. At this point in the method, devices have been made.

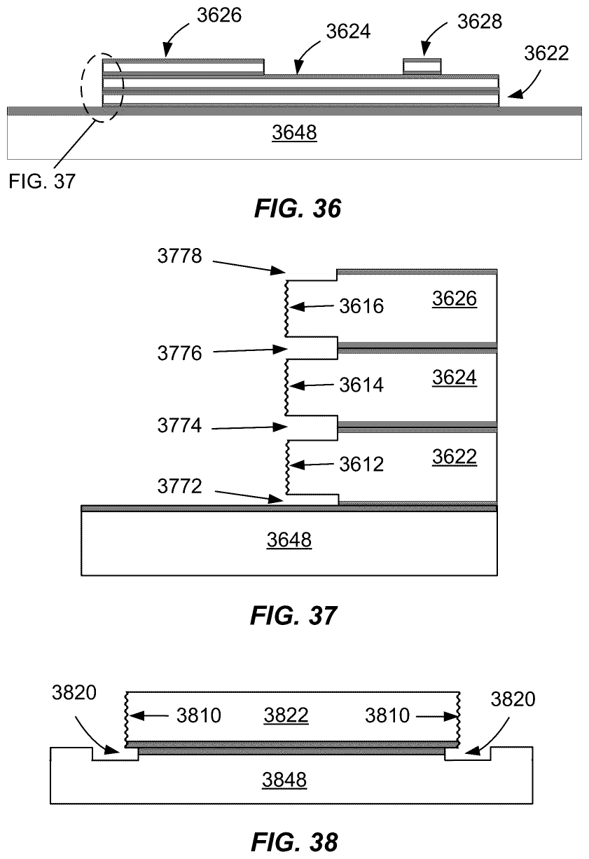

The method previously described can be used to bond a die to another die, as illustrated in FIGS. 36 and 37. In a non-limiting implementation illustrated in FIG. 36, a bonding substrate 3648 can include microprocessor or another relatively large die that is part of a semiconductor wafer. Each of the dies 3622 and 3624 can be memory dies. For example, the die 3622 can be an Level 2 cache, and the die 3624 can be a flash memory. The dies 3622 and 3624 can be the same or different sizes. The die 3626 can be an energy converter, for example, a buck converter that converts 12 VDC to 1 VDC. The die 3628 can be a capacitor having one electrode electrically coupled to a V_{DD} terminal, and another electrode electrically coupled to a V_{SS} terminal to help the voltage difference between the V_{DD} and V_{SS} terminals be more stable as transistors and logic circuits in any one or more of the bonding substrate 3648 and dies 3622, 3624, and 3626 are turned on and off. The die 3622 is a bonding substrate with respect to the die 3624, and the die 3624 is a bonding substrate with respect to the die 3626. The combination of dies described above is exemplary and many other combinations of dies may be used. The dies illustrated in FIG. 36 can be bonded using the methods as previously described.

The upper and lower sides of the dies 3622, 3624, 3626, and 3628 are illustrated as being activated. If no further die will be bonded to the die 3626, its upper surface may or may not be activated, and if no further die will be bonded to the die 3628, its upper surface may or may not be activated.

FIG. 37 includes an enlarged view of a portion of the bonding substrate 3648 and the dies 3622, 3624, and 3626 at the location seen in FIG. 36. The dies 3622, 3624, and 3626 have activated surfaces along opposite surfaces of the dies. A first edge 3772 within the die 3622 is adjacent to the bonding substrate 3648. A gap 3774 includes a second edge of the die 3622 and a first edge of the die 3624, and a gap 3776 includes a second edge of the die 3624 and a first edge of the die 3626. A second edge 3778 within the die 3626 is exposed along the upper side of the die 3626. The first and second edges can allow bonding to be performed without the outer peripheral edges 3612, 3614, and 3616 from contacting a die chuck of the bonding head or its corresponding bonding substrate. Thus, similar to other implementations, particle issues associated with dislodging, generating, or trapping particles can be prevented or substantially reduced.

One or both of the anneals to improve metal contact between a die and its corresponding bonding substrate and to reduce contact resistance may be performed after each die is bonded, after each level of dies are bonded (for example, the dies 3626 and 3628 are at the same level), or only after all dies in FIG. 36 are bonded.

The methods previously described can be used with other die chucks. FIGS. 5 and 6, illustrate different die chucks can be used for bonding heads within the array of bonding heads 124. The methods previously described are applicable to the die chuck 5430 in FIG. 5, may be used for the die chuck having the mesa 6434 and other features in FIG. 6. Other methods may be used for the any of die chucks described herein.

In another implementation, a bonding substrate can have a trench to aid in bonding. FIG. 38 includes a cross-sectional view of a bonding substrate 3848 that defines a trench 3820 that laterally surrounds a bonding site. A die 3822 may not have any of the first and second edges as previously described or may have an edge extending from either major surface or the first and second edges extending from their corresponding major surfaces of the die 3822. The die 3822 has outer peripheral edges 3810 that are formed and have the issues as previously described with respect to the outer peripheral edges 2310. The outer peripheral edges 3810 do not contact the bonding substrate 3848, and thus, the likelihood of particles being trapped between an electronic component region of the die 3822 and the bonding site are less as compared to a bonding substrate without the trench 3820 and none of the first and second edges within the die 3822.

A die may or may not have any a first edge when a die is bonded to a bonding substrate having a trench or another die having a first edge or a second edge corresponding to the outer peripheral edge of the die. Referring to FIG. 37, the die 3624 does not need to have any of the first edge or second edge because the die 3622 has a second edge and the die 3626 has a first edge. Alternatively, the die 3626 does not need to have any of the first edge or the second edge because the die 3624 has a second edge. In another implementation, any or all of the dies 3622, 3624, and 3626 may not have a second edge. The first edge of the die 3624 may be sufficient to prevent or substantially reduce the likelihood of contact of the outer peripheral edge 3612 from contacting the die 3622. The first edge of the die 3626 may be sufficient to prevent or substantially reduce the likelihood of contact of the outer peripheral edge 3614 from contacting the die 3624. Referring to FIG. 38, the die 3822 may or may not have any of the first edge extending from the outer peripheral edge 3810 because the trench 3820 in the bonding substrate 3848 can prevent or substantially reduce the likelihood of contact with the outer peripheral edge 3810.

Implementations as described herein can allow a die to be bonded to a bonding site of a bonding substrate with a reduced likelihood of particles being trapped where the die and the bonding site contact each other. Particles and fractures can be present along the outer peripheral edges of the die. At least some of the particles cannot be removed using a cleaning operation prior to a transfer operation. The particles can be dislodged or generated when the outer peripheral edges contact another object, such as a die chuck or the bonding substrate, or when the die is moved during a transfer cycle. A particle between the die and a die chuck or a bonding substrate may result in at least one unacceptable electrical contact between the die and the bonding site, a tilt misalignment, not allow proper bonding near the edge of the die, or a combination thereof.

Either or both of the first and second edges within buffer regions of the dies can prevent or substantially reduce the likelihood of an object contacting the outer peripheral edges of the dies during the transfer cycle. If a particle becomes dislodged or generated during the transfer cycle, the particle is less likely to be trapped between an electrical component region of the die and the corresponding bonding site.

An edge can be along a single side, or first and second edges can be along opposite sides of a die. When the first and second edges are along opposite sides, a die may be bonded along a device side or a back side of the die. Thus, a decision on which side of the die is to be bonded to a bonding site or whether another die will be bonded to the die can be made after the first and second edges are defined and allow for more manufacturing flexibility. If needed or desired, an edge may be along a single side of the die, and the process flow can be simplified by eliminating a pair of mask and etch operations.

The first and second edges can be formed with sidewalls that are vertical or nearly vertical as illustrated in FIG. 14. The vertical or nearly vertical sidewalls can allow for improved registration and metrology operations with respect to bonding the die to a bonding site of the bonding substrate. Other shapes for the sidewalls can be used, and some exemplary shapes are illustrated in FIGS. 15 to 17.

Mask members can be formed to have rounded corners, such as illustrated in FIG. 11. The rounded corners of the mask members can allow the mesas (unetched portions of the dies) to have mesa edges that are rounded as illustrated in FIG. 24. Thus, mesas can be formed without sharp corners as seen from a top view of the dies.

Note that not all of the activities described above in the general description or the examples are required, that a portion of a specific activity may not be required, and that at least one further activities can be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that can cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations can also be provided in combination in a single implementation, and conversely, various features that are, for brevity, described in the context of a single implementation, can also be provided separately or in any subcombination. Further, reference to values stated in ranges includes each and every value within that range. Many other implementations can be apparent to skilled artisans only after reading this specification. Other implementations can be used and derived from the disclosure, such that a structural substitution, logical substitution, or another change can be made without departing from the scope of the disclosure. Accordingly, the disclosure is to be regarded as illustrative rather than restrictive.

What is claimed is:

1. A method, comprising:
creating a first edge in a workpiece that includes a die and a dicing lane adjacent to the die, wherein the first edge extends from a first major surface of the die to at least the dicing lane;
dicing the workpiece to separate the die from a remainder of the workpiece, wherein dicing forms an outer peripheral edge of the die and is performed after creating the first edge; and
bonding the die to a bonding site, wherein, during bonding, the outer peripheral edge does not contact the bonding site or does not contact a chucking surface of a bonding head chuck.

2. The method of claim 1, further comprising:
bowing the die away from the chucking surface before bonding the die to the bonding site.

3. The method of claim 1, wherein creating the first edge comprises etching the workpiece.

4. The method of claim 1, further comprising:
creating a second edge in the workpiece, wherein the second edge extends from a second major surface of the die to at least the dicing lane, and the second major surface is opposite the first major surface.

5. The method of claim 4, further comprising:
backgrinding or lapping the workpiece, wherein backgrinding is performed after creating the first edge and before creating the second edge.

6. The method of claim 5, wherein backgrinding or lapping the workpiece is performed such that a feature is exposed along a background surface.

7. The method of claim 6, wherein backgrinding or lapping the workpiece is performed such that the feature includes a through-substrate via.

8. The method of claim 6, wherein backgrinding or lapping the workpiece is performed such that the feature is an alignment feature.

9. The method of claim 4, wherein the die has a die area corresponding to the outer peripheral edge, and the chucking surface has a chucking area that is larger than the die area.

10. The method of claim 9, wherein bonding the die to the bonding site is performed such that, wherein, during bonding, the outer peripheral edge does not contact the chucking surface of the bonding head chuck.

11. The method of claim 3, wherein, during transferring the die, the first edge has a first sidewall, a second sidewall, and a rounded corner between the first sidewall and the second sidewall.

12. The method of claim 1, wherein creating the first edge is performed such that a transition from the first major surface to a bottom surface of the first edge is characterized by a step.

13. The method of claim 1, wherein creating the first edge is performed such that the first edge has an arc shape or a chamfered shape, wherein the arc shape or the chamfered shape extends laterally in a range from 2% to 100% of a distance from the first major surface to the dicing lane.

14. The method of claim 1, wherein bonding the die to the bonding site is performed such that the bonding site is part of a bonding substrate that defines a trench, and, after bonding the die to the bonding site, the outer peripheral edge overlaps the trench.

15. The method of claim 1, further comprising performing a check to ensure the first edge is on the die before bonding the die to the bonding site.

16. A method of manufacturing a device, comprising:
creating a first edge in a workpiece that includes a die and a dicing lane adjacent to the die, wherein the first edge extends from a first major surface of the die at least to the dicing lane;
dicing the workpiece to separate the die from a remainder of the workpiece, wherein dicing forms an outer peripheral edge of the die and is performed after creating the first edge; and
bonding the die to a bonding site, wherein, during bonding, the outer peripheral edge does not contact the bonding site or does not contact a chucking surface of a bonding head chuck.

17. A method, comprising:
creating a first edge in a workpiece that includes a die and a dicing lane adjacent to the die, wherein the first edge extends from a first major surface of the die at least to the dicing lane;
creating a second edge in the workpiece, wherein the second edge extends from a second major surface that is opposite the first major surface, and the second edge overlaps or underlaps at least a portion of the first edge and extends laterally at least to the dicing lane;
dicing the workpiece along the dicing lane to separate the die from a remainder of the workpiece, wherein, after dicing, the die has an outer peripheral edge between the first major surface and the second major surface;
transferring the die to a bonding head having a bonding head chuck having a chucking surface; and
bonding the die to a bonding site.

18. The method of claim 17, further comprising:
bowing the die away from the chucking surface before bonding the die,
wherein, during bonding, the outer peripheral edge does not contact each of the chucking surface and the bonding site.

19. The method of claim 17, further comprising:
backgrinding or lapping the workpiece, wherein backgrinding is performed after creating the first edge and before creating the second edge.

20. A bonding apparatus, comprising:
a bonding head including a bonding head chuck, wherein:
the bonding head chuck has a chucking surface that has a chucking area, a first land extending to the chucking surface, and a second land extending to the chucking surface,
the second land is spaced apart from and laterally surrounded by the first land,
a first zone is disposed between the first land and the second land, and
a second zone is laterally surrounded by the second land;
a first pressure actuator adapted to provide a first vacuum within the first zone, wherein the first vacuum is sufficient to a hold a die that has a first major surface and a second major surface opposite the first major surface, an outer peripheral edge between the first major surface and the second major surface, and a die area corresponding to the outer peripheral edge, wherein the die area is less than the chucking area;
a second pressure actuator and adapted to provide a pressure to the second zone, wherein the pressure is sufficient to bow the die while the die is being held by the first vacuum within the first zone; and
a controller adapted to provide instructions including:
activating the first pressure actuator to hold the die;
activating the second pressure actuator to bow the die; and
bonding the die to a bonding site after activating the second pressure actuator, wherein, during each of activating the second pressure actuator and bonding, the outer peripheral edge does not contact each of the chucking surface and the bonding site.

21. The bonding apparatus of claim 20, wherein the bonding head further comprises:
a bonding head body coupled to the bonding head chuck.

22. The bonding apparatus of claim 20, wherein the controller is adapted to provide a further instruction including:
deactivating the second pressure actuator after the die contacts the bonding site and before completion of bonding the die.
